(19) United States
(12) Patent Application Publication
(10) Pub. No.: US 2025/0115997 A1
(43) Pub. Date: Apr. 10, 2025

(54) LASER-TEXTURED SURFACE AND MEHODS OF FORMING SAME

(71) Applicant: Eugenus, Inc., San Jose, CA (US)

(72) Inventors: Behzad Mahmoudi, Milpitas, CA (US); Sung-Hoon Jung, Santa Clara, CA (US); Hae Young Kim, San Jose, CA (US)

(21) Appl. No.: 18/482,790

(22) Filed: Oct. 6, 2023

(51) Int. Cl. C23C 16/455; B23K 26/352

(52) U.S. Cl. CPC C23C 16/45565; B23K 26/355

(57) ABSTRACT

A gas diffuser plate configured to diffuse gases delivered into a cyclic deposition chamber is disclosed. The gas diffuser plate as fabricated comprising a gas diffuser plate having a laser-textured surface configured to face a substrate when present in the cyclic deposition chamber. The laser-textured surface comprises microstructures that serve to provide an emissivity of the gas diffuser plate between about 0.2 and about 0.9. The gas diffuser plate further comprises a corrosion-resistant material coating the laser-textured surface. The emissivity of the gas diffuser plate is at least partially based on the parameters of the processing laser.

### BACKGROUND

### Field

The disclosed technology relates generally to thin film deposition systems, and more particularly to showerhead assemblies for vapor deposition systems.

### Description of the Related Art

As semiconductor devices continue to scale in lateral dimensions, there is a corresponding scaling of vertical dimensions of the semiconductor devices, including thickness scaling of the functional thin films such as electrodes and dielectrics. Semiconductor fabrication involves various thin films that are deposited and patterned throughout the process flow. The thin films employed in semiconductor fabrication can be formed using various techniques, including wet and dry deposition methods. Wet deposition methods include, e.g., aerosol/spray deposition, sol-gel method and spin-coating. Dry deposition methods include physical vapor-based techniques, e.g., physical vapor deposition (PVD) and evaporation. Dry deposition methods additionally include precursor and/or chemical reaction-based techniques, e.g., chemical vapor deposition (CVD) and cyclic deposition such as atomic layer deposition (ALD).

### SUMMARY

In one aspect, a gas diffuser plate configured to diffuse gases delivered into a cyclic deposition chamber is disclosed. The gas diffuser plate as fabricated comprises a gas diffuser plate having a laser-textured surface configured to face a substrate when present in the cyclic deposition chamber. In some aspects, the laser-textured surface comprises microstructures to provide an emissivity of the gas diffuser plate between about 0.2 and about 0.9. In some aspects, the gas diffuser plate further comprises a corrosion-resistant material coating the laser-textured surface. In some aspects, the laser-textured surface comprises stripes of laser scanning marks extending in a direction parallel to a laser scanning direction characteristic of laser texturing. In some aspects, the stripes correspond to regions where laser scanning lines overlap. In some aspects, the laser scanning marks comprise microstructures having substantially different sizes or textures relative to sizes or textures of microstructures in regions of the laser-textured surface between adjacent laser scanning marks where laser scanning lines do not overlap. In some aspects, the corrosion-resistant material substantially does not change the emissivity of the gas diffuser plate such that the gas diffuser plate having the corrosion-resistant material coated thereon has an emissivity between about 0.2 and about 0.9. In some aspects, the emissivity of the gas diffuser plate is between about 0.4 and about In some aspects, the laser-textured surface is configured to modulate the emissivity of the gas diffuser plate to match an emissivity of a deposited material on the substrate. In some aspects, the microstructures have a general shape of a dome or a pillar. In some aspects, the microstructures have an average peak-to-valley height of about 1 micrometer to 10 micrometers. In some aspects, the microstructures have an average peak-to-valley height of about 2 micrometers to 5 micrometers. In some aspects, the microstructures have an average width measured at bases thereof of about 1 micrometer to 10 micrometers. In some aspects, each microstructure comprises a metal core integrally protruding from a bulk substrate portion of the gas diffuser plate, and further comprises a layer of oxide formed on the metal core. In some aspects, each microstructure has formed on a surface thereof a plurality of nanostructures, wherein the nanostructures have a maximum dimension that is smaller than a maximum dimension of the microstructures by at least two orders of magnitude. In some aspects, the nanostructures comprise an average size of less than 10 nm. In some aspects, the corrosion-resistant material is configured to reduce particle contamination generated from corrosion of the gas diffuser plate by a fluorine-containing cleaning gas. In some aspects, the corrosion-resistant material is resistant to the corrosion of a fluorine-containing cleaning gas when present in the cyclic deposition chamber. In some aspects, the fluorine-containing cleaning gas comprises NF₃, F₂, Ar, ClF₃, or combinations thereof. In some aspects, the corrosion-resistant material comprises aluminum oxide. In some aspects, the corrosion-resistant material is transparent or translucent. In some aspects, the corrosion-resistant material is deposited by a method comprising atomic layer deposition (ALD). In some aspects, the laser-textured surface reduces an amount of radiation emission from the substrate being reflected by the gas diffuser plate. In some aspects, the laser-textured surface comprises a plurality of regions. In some aspects, each region has an emissivity value different from those of neighboring regions by at least 10%. In some aspects, the plurality of regions is arranged as concentrically defined rings.

In another aspect, a gas diffuser plate for diffusing gases delivered into a cyclic deposition chamber configured to deposit a material on a wafer is disclosed. The gas diffuser plate as fabricated comprises a diffuser plate having a laser-textured surface at a side configured to face the wafer when present in the cyclic deposition chamber; and a corrosion-resistant coating formed on the laser-textured surface. In some aspects, the laser-textured surface comprises stripes of laser scanning marks extending in a direction parallel to a laser scanning direction characteristic of laser texturing. In some aspects, the stripes correspond to regions where laser scanning lines overlap. In some aspects, the laser scanning marks comprise microstructures having substantially different sizes or textures relative to sizes or textures of microstructures in regions of the laser-textured surface between adjacent laser scanning marks where laser scanning lines do not overlap. In some aspect, the laser-textured surface comprises microstructures to provide an emissivity of the gas diffuser plate between about 0.2 and about 0.9. In some aspect, the corrosion-resistant coating is configured to reduce particle generation from the corrosion of the laser-textured surface or the diffuser plate. In some aspect, the laser-textured surface is configured to modulate the emissivity of the gas diffuser plate to a value between about 0.4 and about 0.65. In some aspect, the corrosion-resistant coating is corrosion resistant to a cleaning gas comprising a fluorine-containing gas. In some aspect, the fluorine-containing comprises NF₃, F₂, Ar, ClF₃, or combinations thereof. In some aspect, the laser-textured surface reduces an amount of radiation emission from the wafer being reflected by the gas diffuser plate. In some aspect, the microstructures comprise a general shape of a dome or a pillar. In some aspect, the microstructures comprise an average peak-to-valley height of about 1 micrometer to 10 micrometers. In some aspect, the microstructures comprise an average peak-to-valley height of about 2 micrometers to 5 micrometers. In some aspect, the microstructures comprise a width measured at bases thereof of about 1 micrometer to 10 micrometers. In some aspect, each microstructure comprises a metal core integrally protruding from a bulk substrate portion of the gas diffuser plate, and further comprises a layer of oxide formed on the metal core. In some aspect, each microstructure has formed on a surface thereof a plurality of nanostructures, wherein the nanostructures have a maximum dimension that is smaller than a maximum dimension of the microstructures by at least two orders of magnitude. In some aspect, the nanostructures comprise an average size of less than 10 nm. In some aspect, the corrosion-resistant coating comprises aluminum oxide. In some aspect, the corrosion-resistant coating is deposited by a method comprising atomic layer deposition (ALD). In some aspects, the laser-textured surface comprises a plurality of regions. In some aspects, each region has an emissivity value different from those of neighboring regions by at least 10%. In some aspects, the plurality of regions is arranged as concentrically defined rings.

In another aspect, a method of fabricating a diffuser plate for diffusing gases delivered into a cyclic deposition chamber is disclosed. The method of fabricating the diffuser plate comprises providing a substrate diffuser plate having a substrate emissivity; and texturing a surface of the substrate gas diffuser plate with a pulsed laser beam to form a laser-textured surface comprising microstructures, such that the laser-textured surface has an emissivity that is higher than the substrate emissivity and between about 0.2 and about 0.9. In some aspects, texturing comprises consecutive line scanning the surface of the substrate gas diffuser plate with the pulsed laser beam. In some aspects, the pulsed laser beam overlaps with another pulsed laser beam in adjacent line scanning. In some aspect, texturing comprises scanning with the laser beam at a scanning speed of about 60 mm/s to about 200 mm/s. In some aspect, the laser beam has a pulse energy of about 15 μJ to about 40 μJ. In some aspect, the emissivity is between about 0.2 to about 0.7. In some aspect, the method further comprises forming a protective layer on the laser-textured surface. In some aspect, forming the protective layer comprises depositing by atomic layer deposition. In some aspect, the protective layer is a conformal layer. In some aspects, the laser-textured surface comprises a plurality of regions. In some aspects, each region has an emissivity value different from those of neighboring regions by at least 10%. In some aspects, the plurality of regions is arranged as concentrically defined rings.

In another aspect, a diffuser plate having a laser-textured surface for a cyclic deposition process is disclosed. The laser-textured surface comprises microstructures configured to provide an emissivity of the gas diffuser plate between about 0.2 and about 0.9. In some aspects, the microstructures comprise an average peak-to-valley height of about 1 to 10 micrometers. In some aspects, a conformal protective layer formed on the laser-textured surface. In some aspects, the laser-textured surface comprises stripes of laser scanning marks extending in a direction parallel to a laser scanning direction characteristic of laser texturing. In some aspects, the stripes correspond to regions where laser scanning lines overlap. In some aspects, the laser scanning marks comprise microstructures having substantially different sizes or textures relative to sizes or textures of microstructures in regions of the laser-textured surface between adjacent laser scanning marks where laser scanning lines do not overlap. In some aspects, the laser-textured surface comprises a plurality of regions. In some aspects, each region has an emissivity value different from those of neighboring regions by at least 10%. In some aspects, the plurality of regions is arranged as concentrically defined rings.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

These and other features, aspects, and advantages of the present disclosure are described with reference to the drawings of certain embodiments, which are intended to illustrate certain embodiments and not to limit the invention.

FIG. 1 schematically illustrates a thin film deposition system including a deposition chamber configured to deliver precursors using a showerhead assembly comprising a diffuser plate, according to embodiments.

FIG. 2A illustrates a fresh diffuser plate having a relatively low emissivity (brighter) and a stabilized diffuser plate having a relatively high emissivity (darker).

FIG. 2B schematically illustrates the relationship between growth per cycle (GPC) with deposition time for each fresh diffuser plate without a laser-textured surface.

FIG. 2C schematically illustrates the relationship between growth per cycle (GPC) with deposition time for each fresh diffuser plate with a laser-textured surface.

FIG. 3 schematically illustrates a flat surface with high reflection.

FIG. 4 schematically illustrates a substrate having a laser-textured surface having a low reflection.

FIG. 5 schematically illustrates two options for coating the laser-textured surface on a substrate according to some embodiments.

FIG. 6A shows an image of a laser-textured diffuser plate according to some embodiments.

FIG. 6B illustrates the images of the laser-textured samples formed with different laser parameters according to some embodiments.

FIG. 7 illustrates the microscopic images of the laser-textured samples illustrated in FIG. 6B.

FIG. 8A illustrates an optical image of a laser-textured surface formed according to some embodiments.

FIG. 8B illustrates a three-dimensional surface roughness image of the laser-textured surface of the sample in FIG. 8A.

FIG. 9A illustrates a two-dimensional surface roughness image of the laser-textured surface of the sample shown in FIG. 8A.

FIG. 9B illustrates a roughness profile in X direction of the sample in FIG. 8A.

FIG. 9C illustrates a roughness profile in Y direction of the sample shown in FIG. 8A.

FIG. 10A illustrates an optical image of a laser-textured surface formed according to some embodiments.

FIG. 10B illustrates a three-dimensional surface roughness image of a laser-textured surface of the sample in FIG. 10A.

FIG. 10C illustrates a two-dimensional surface roughness image of the laser-textured surface of the sample in FIG. 10A.

FIG. 10D illustrates a roughness profile in X direction of the sample shown in FIG. 10A.

FIG. 10E illustrates a roughness profile in Y direction of the sample shown in FIG. 10A.

FIG. 11A illustrates the laser-textured substrate samples with different laser processing parameters according to some embodiments.

FIG. 11B shows an enlarged image of the laser-processed substrate samples with different laser processing parameters in FIG. 11A.

FIGS. 12A-12F show the microscopic images of the laser-textured surfaces covered by white crystal structures with different magnifications.

FIG. 13A illustrates a two-dimensional roughness profile of a laser-textured surface covered by white crystal structures with a ×1000 magnification.

FIG. 13B illustrates a three-dimensional roughness profile of a laser-textured surface covered by the white crystal structures in FIG. 13A.

FIGS. 13C and 13D illustrate the roughness profile of the sample along the scanning routes as shown in FIG. 13A.

FIGS. 14A-14F illustrate the scanning electron microscope (SEM) images of a laser-textured sample according to some embodiments.

FIGS. 15A-15F illustrate the SEM images of a laser-textured sample according to some embodiments.

FIG. 16 shows an SEM image of the microstructures formed by the laser processing according to some embodiments.

FIG. 17 shows an SEM image of the microstructures formed by the laser processing according to some embodiments.

FIG. 18A shows an SEM image of the microstructures formed by the laser processing according to some embodiments.

FIGS. 18B-18D illustrate the cross-section view of microstructures cut in X direction according to some embodiments with different magnifications.

FIG. 18E illustrates the elemental analysis of a cross section of one microstructure according to some embodiments.

FIG. 19A shows an SEM image of the microstructures formed by the laser processing according to some embodiments.

FIGS. 19B-19D illustrate the cross-section view of microstructures cut in Y direction according to some embodiments with different magnifications.

FIG. 20 illustrates different spots on the cross section of the microstructures for elemental analysis.

FIG. 21A illustrates the spectral reflectivity versus wavelength of laser-textured samples according to some embodiments.

FIG. 21B shows SEM images of a laser-textured sample according to some embodiments.

FIGS. 22A-22E illustrate the surface roughness of laser-textured samples according to some embodiments.

FIG. 23 illustrates the illustrates the spectral reflectivity versus wavelength of laser-textured samples according to some embodiments.

FIGS. 24A-24B show the SEM images of the surface of a laser-textured sample according to some embodiments with different angles.

FIGS. 24C-24D show the SEM images of the surface of a laser-textured sample according to some embodiments with different angles.

FIGS. 25A-25B show the SEM images of the surface of a laser-textured sample according to some embodiments with different angles.

FIGS. 25C-25D show the SEM images of the surface of a laser-textured sample according to some embodiments with different angles.

FIGS. 26A-26D illustrate the surface roughness of laser-textured samples according to some embodiments.

FIGS. 27A-27D illustrate the roughness profile in Y direction of laser-textured samples according to some embodiments.

FIG. 28 shows an SEM image of the laser-textured surface formed according to some embodiments.

FIG. 29 shows an SEM image of the laser-textured surface formed according to some embodiments.

FIGS. 30A-30D show the surface roughness of the laser-processed samples according to some embodiments.

FIG. 31A shows an image of a laser-processed sample covered with a dense aluminum oxide layer according to some embodiments.

FIG. 31B shows an image of the sample shown in FIG. 31A after being cleaned with ClF₃ according to some embodiments.

FIG. 31C illustrates a top view SEM image of the surface of the sample shown in FIG. 31B after the ClF₃ processing.

FIG. 31D illustrates a titled SEM image of the surface of the sample shown in FIG. 31B after the ClF₃ processing.

FIG. 31E illustrates the EDS spectrum of a spot on the surface of the sample illustrated shown in FIG. 31B.

FIGS. 31F and 31G illustrate the cross-section view of the sample shown in FIG. 31B after ClF₃ cleaning with different magnifications.

FIG. 31H illustrates a top down view of the sample shown in FIG. 31B after the ClF₃ cleaning process with a ×2000 magnification.

FIG. 32A shows an image of a laser-processed substrate sample covered with a dense aluminum oxide layer according to some embodiments.

FIG. 32B shows an image of the sample shown in FIG. 32A after being cleaned with ClF₃ according to some embodiments.

FIG. 32C illustrates a top view SEM image of the surface of the sample shown in FIG. 32B after the ClF₃ processing.

FIG. 32D illustrates a titled SEM image of the surface of the sample shown in FIG. 32B after the ClF₃ processing.

FIG. 32E illustrates the EDS spectrum of a spot on the surface of the sample illustrated in FIG. 32B.

FIGS. 32F and 32G illustrate the cross-section view of the sample shown in FIG. 32B after ClF₃ cleaning with different magnifications.

FIG. 32H illustrates a top down view of the sample shown in FIG. 32B after the ClF₃ cleaning process with a ×2000 magnification.

FIG. 33A shows an image of a laser-processed substrate sample covered with a dense aluminum oxide layer according to some embodiments.

FIG. 33B shows an image of the sample shown in FIG. 33A after being cleaned with ClF₃ according to some embodiments.

FIG. 33C illustrates a top view SEM image of the surface of the sample shown in FIG. 33B after the ClF₃ processing.

FIG. 33D illustrates a titled SEM image of the surface of the sample shown in FIG. 33B after the ClF₃ processing.

FIG. 33E illustrates the EDS spectrum of a spot on the surface of the sample illustrated in FIG. 33B.

FIGS. 33F and 33G illustrate the cross-section view of the sample shown in FIG. 33B after ClF₃ cleaning with different magnifications.

FIG. 33H illustrates a top down view of the sample shown in FIG. 33B after the ClF₃ cleaning process with a ×2000 magnification.

FIG. 34A shows an image of a laser-processed substrate sample covered with a dense aluminum oxide (AlO) layer according to some embodiments.

FIG. 34B shows an image of the sample shown in FIG. 34A after being cleaned with ClF₃ according to some embodiments.

FIG. 34C illustrates a top view SEM image of the surface of the sample shown in FIG. 34B after the ClF₃ processing.

FIG. 34D illustrates a titled SEM image of the surface of the sample shown in FIG. 34B after the ClF₃ processing.

FIG. 34E illustrates the EDS spectrum of a spot on the surface of the sample illustrated in FIG. 34B.

FIGS. 34F and 34G illustrate the cross-section view of the sample shown in FIG. 34B after ClF₃ cleaning with different magnifications.

FIG. 34H illustrates a top down view of the sample shown in FIG. 3B after the ClF₃ cleaning process with a ×2000 magnification.

FIG. 35 illustrates the plot of the spectral reflectivity versus wavelength of the samples covered with protective top-coatings having different thickness according to some embodiments.

### DETAILED DESCRIPTION OF THE PREFERRED EMBODIMENT

Cyclic deposition processes such as atomic layer deposition (ALD) processes can provide a relatively conformal thin films on relatively high aspect-ratio (e.g., 2:1) structures with high uniformity and thickness precision. While generally less conformal and uniform compared to ALD, thin films deposited using continuous deposition processes such as chemical vapor deposition (CVD) can provide higher productivity and lower cost. ALD and CVD can be used to deposit a variety of different films including elemental metals, metallic compounds (e.g., TiN, TaN, etc.), semiconductors (e.g., Si, III-V, etc.), dielectrics (e.g., SiO₂, AlN, HfO₂, ZrO₂, etc.), rare-earth oxides, conducting oxides (e.g., IrO₂, etc.), ferroelectrics (e.g., PbTiO₃, LaNiO₃, etc.), superconductors (e.g., Yba₂Cu₃O₇₋ₓ), and chalcogenides (e.g., GeSbTe), to name a few.

Some cyclic deposition processes such as atomic layer deposition (ALD) include alternatingly exposing a substrate to a plurality of precursors to form a thin film. The different precursors can alternatingly at least partly saturate the surface of the substrate and react with each other, thereby forming the thin film in a layer-by-layer fashion. There are different types of ALD, including time-based ALD and spatial ALD. In a time-based ALD, precursors are injected sequentially, reacting one at a time with active sites on the substrate surface. The exposures to precursors may be separated by a purge step in order to prevent mixing and reaction of precursors in the gas phase. The reaction is thus surface-limited and self-terminating, yielding uniform deposition. In addition, many ALD processes can allow for deposition of high-quality materials at substantially lower temperatures than with CVD, even near room temperature. ALD growth can take place in a particular temperature window, below which precursor molecules may not be sufficiently activated or desorption can be too slow, and above which precursors can decompose at the surface or even before reaching it, and desorption can be too fast during the purge step.

Because of the layer-by-layer growth capability, ALD can enable precise control of the thickness and the composition, which in turn can enable precise control of various properties such as conductivity, conformality, uniformity, barrier properties and mechanical strength. In particular, due to thickness scaling that often accompanies feature size scaling in semiconductor devices, there is an increasing need to improve the within-wafer uniformity even for ALD that is already known to produce thin films with very high uniformity relative to other techniques. Although ALD films generally have excellent uniformity, there may be several reasons why the uniformity could be degraded during deposition. The uniformity could be degraded due to, e.g., overlapping reactant pulses, non-uniform precursor distribution, thermal self-decomposition of precursors, and non-uniformities in substrate temperature, to name a few.

Non-uniform precursor distributions can be caused by limited diffusion or mixing with carrier gases. For example, in ALD reactors, the precursors are introduced to the reaction chamber from individual source delivery lines, and the lines may be brought together to a common in-feed line prior to being introduced into the reaction chamber. Without being bound to any theory, a carrier gas, which may be flowing through all precursor delivery lines, can sometimes result in the carrier gas from one precursor delivery line serving as a diffusion barrier for the precursor flowing from a different precursor delivery line. Although the precursor would get properly mixed with the carrier gas in the individual source delivery line, the precursor may not properly spread out beyond the intersection of the common reactor in-feed line that is usually located a short distance from the substrate in the upstream direction.

To mitigate these concerns, some reactor chambers employ a means for distributing precursor/reactant and purge gases within the reactor volume. One such means includes a showerhead employed to effectively distribute and mix gases including precursors. Design variations of this hardware can range from flat designs to tapered designs. Gas distribution can be provided in one of several ways, including (1) across the surface of the showerhead via a plurality of holes supplied by one or more plenums, (2) fed from the center of the showerhead or (3) from one end to the other (also referred to as cross-flow).

In order to reduce the above-noted non-uniformity issues arising from insufficient mixing or diffusion, some ALD reactors, e.g., reactors with flat showerheads and distributed holes, a larger spacing between the showerhead and the substrate to increase the mixing and diffusion and reduce the effects of gas impingement on the substrate. However, increased spacing between the showerhead and the substrate comes at a price of longer ALD cycle times due to increased volume to fill with gases and purge. In time-based ALD, longer time needed to fill and purge the reactor can also worsen the non-uniformity arising from overlapping reactant pulses, because there may be longer leading and trailing edges for precursor pulses. In spatial ALD reactors with flat showerheads, spacing can be smaller but there may also typically a leading and trailing edge effect.

Furthermore, the inventors have found that, for the stringent requirements of today's semiconductor manufacturing specifications, process drift during ALD process may reduce film qualities, for example, by causing variation in film thickness, or causing variation in film qualities such as electrical or mechanical properties. The inventors have found that the ALD process stabilizes after seasoning or conditioning of a fresh diffuser plate, for example, by running a plurality of deposition cycles with test wafers (i.e., dummy wafers). The time to stabilize the ALD process is a process drift time, also known as conditioning time or seasoning time. The inventors have found that the radiosity in a deposition chamber, including the energy exchange between a showerhead and a wafer substrate caused by the temperature difference between the showerhead and the wafer substrate, can cause temperature fluctuation at the showerhead and on the wafer substrate. Such temperature fluctuation on the wafer substrate translates to within-wafer nonuniformities of various parameters, including growth rate, thickness, resistivity, step coverage, etc. The inventors have also found that, the temperature fluctuations on the wafer substrate caused by the radiation emission from the wafer and showerhead may be reduced after a fresh diffuser plate is used for a certain number of cycles. However, such stabilization requires relative long time and wastes many test wafers (dummy wafers), which reduces the productivity rate.

Thus, there is a need for a diffuser plate for a showerhead assembly for improved productivity (e.g., less time to stabilize the showerhead and substrate temperature) and uniformity of the thin films deposited in ALD systems. To address these and other sources of non-uniformities, various embodiments disclosed herein relate to a gas diffuser plate having a laser-textured surface, wherein the gas diffuser plate with the laser-textured surface has an emissivity higher than the emissivity of the gas diffuser plate with a flat surface. In some embodiments, the laser-textured surface is formed by laser-processing. In some embodiments, the laser-textured surface is coated with a protective layer thereon. In some embodiments, the protective layer is formed by atomic layer deposition.

### A. SHOWERHEAD ASSEMBLY FOR ALD PROCESSES

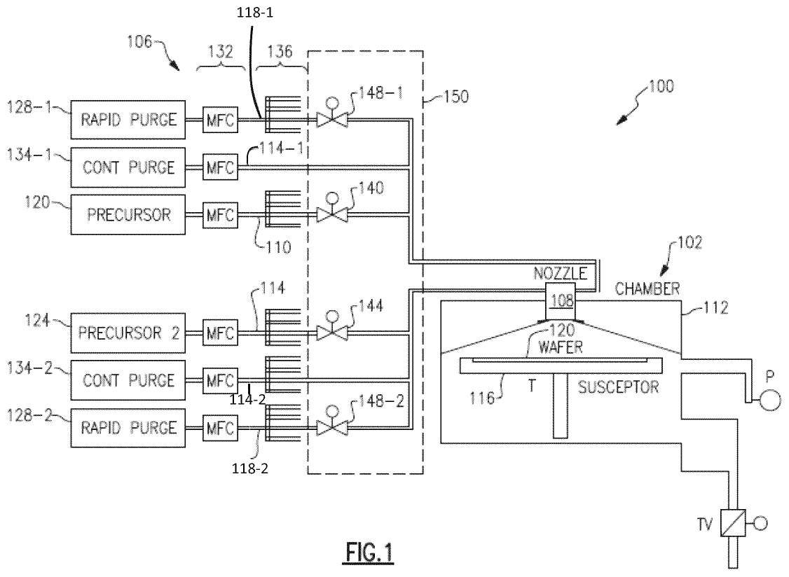

For illustrative purposes only, in the illustrated configuration of FIG. 1, the plurality of precursors may include a first precursor and a second precursor. The first precursor is stored in at least one first precursor source 120, and the second precursor is stored in at least one second precursor source 124. The precursor delivery system 106 is configured to deliver the first and second precursors from the first and second precursor sources 120, 124 into the deposition chamber 102 through first and second precursor delivery lines 110, 114, respectively. A rapid purge (RP) gas can be stored in at least two RP gas sources 128-1, 128-2. The precursor delivery system 106 is configured to deliver the rapid purge (RP) gas from the RP gas sources 128-1, 128-2 into the deposition chamber 102 through respective ones of RP gas delivery lines 118-1, 118-2.

The first and second precursors are configured to be delivered from the first and second precursor sources 120, 124, respectively, by independently actuating first and second precursor atomic layer deposition (ALD) valves 140 and 144 that are connected in parallel to the showerhead assembly 112. Additionally, the RP purge gas is configured to be delivered from the RP purge gas sources 128-1, 128-2 by independently actuating two respective purge gas atomic layer deposition (ALD) valves 148-1, 148-2 that are connected in parallel to the common gas distribution plate 112. The ALD valves 140, 144, 148-1 and 148-2 and the respective delivery lines connected to the showerhead assembly 112 can be arranged to feed the respective gases into the nozzle 108 through a multivalve block assembly 150, which may be attached to a lid of the deposition chamber 102. In the illustrated configuration, the ALD valves 140, 144, 148-1 and 148-2 are final valves before the respective gases are introduced into the deposition chamber 102.

In various configurations of the deposition chamber 102 described herein, a showerhead assembly 112 may include a diffuser plate facing the susceptor 116. As described herein, a diffuser plate refers to a plate comprising a plurality of holes for diffusing precursor gases prior to delivery into the chamber. In some configurations, the plurality of holes may be formed at a portion, e.g., a central portion, of the diffuser plate, while in other configurations, the plurality of holes may be formed substantially throughout the entire surface portion of the diffuser plate facing the substrate. In some configurations, the diffuser plate may be integrated as part of the showerhead assembly 112 while in other configurations, the diffuser plate may be configured as a separate component that can be attached between the showerhead assembly 112 the susceptor 116. In various configurations, the diffuser plate may directly face the substrate when present, or the substrate when no substrate is present, without intervening components.

By way of example only, the first and second precursors can include TiCl₄ and NH₃, respectively, that are delivered into the deposition chamber 102 from respective TiCl₄ and NH₃ sources through respective precursor delivery lines to form, e.g., TiN. The precursor delivery system can additionally be configured to deliver Ar as the purge gas into the process chamber from Ar sources through purge gas delivery lines. Purge gases may be delivered as a continuous purge (CP) gas, which may be delivered through precursor ALD valves, and/or as a rapid purge (RP) gas, which may be delivered through dedicated purge gas ALD valves as shown in FIG. 1. The illustrated precursor delivery system 100 can be configured to deliver Ar as an RP gas into the process chamber 102 from the purge gas sources 128-1, 128-2 through respective purge gas delivery lines and purge gas ALD valves 148-1, 148-2.

According to various embodiments, the thin film deposition system 100 is configured for thermal ALD without an aid of plasma. While plasma-enhanced processes such as plasma enhanced atomic layer deposition (PE-ALD) may be effective in forming conformal films on surfaces having relatively low aspect ratios, such processes may not be effective in depositing films inside vias and cavities having relative high aspect ratios. Without being limited by theory, one possible reason for this is that a plasma may not reach deeper portions of high aspect ratio vias under some circumstances. In these circumstances, different portions of the vias may be exposed to different amounts of the plasma, leading to undesirable structural effects arising from non-uniform deposition, such as thicker films being deposited near the opening of the via compared to deeper portions (sometimes called cusping or keyhole formation). For these reasons, a thermal cyclic vapor deposition such as thermal ALD may be more advantageous, because such thermal processes do not depend on the ability of the plasma to reach portions of the surface being deposited on.

### B. EMISSIVITY OF GAS DIFFUSER PLATE FOR A SHOWERHEAD ASSEMBLY

As described herein, emissivity is defined as the ratio of the energy radiated from a material's surface to that radiated from a perfect emitter, known as a blackbody, at the same temperature and wavelength and under the same viewing conditions. It is a dimensionless number between 0 (for a perfect reflector) and 1 (for a perfect emitter). The emissivity of a certain material may be related to temperature and wavelength of the radiation from the surface of the material. Reflectivity is a measure of the ability of a surface to reflect radiation, which can be related to the emissivity by the expression: Emissivity+Reflectivity=100%.

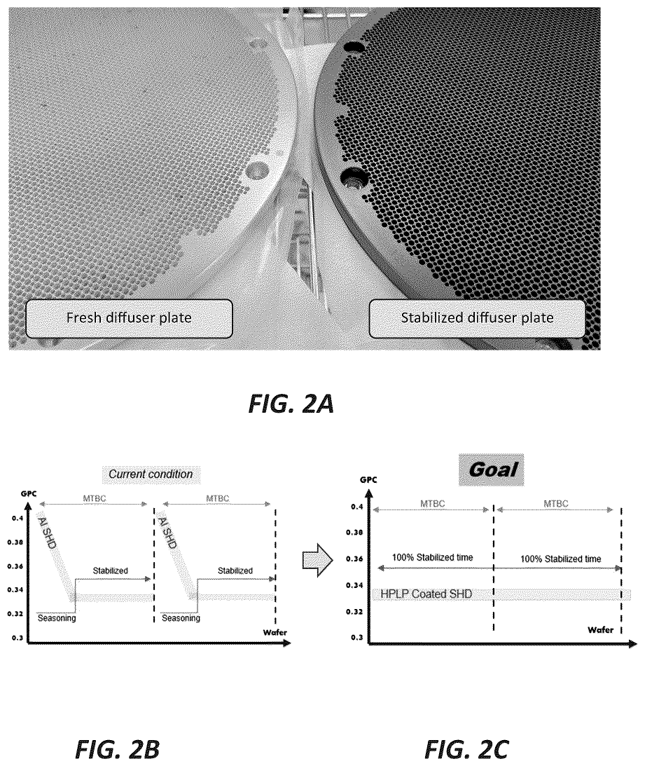

FIG. 2A illustrates a fresh diffuser plate and a stabilized diffuser plate. In some embodiments, the diffuser plate may comprise aluminum or aluminum-based material. As shown in FIG. 2A, the fresh diffuser plate has not been used in any deposition cycle or has been cleaned, and has a lighter silver color and a high reflectivity. The stabilized diffuser plate is a diffuser plate that has been used in a deposition process for a certain number of cycles and has a low reflectivity. According to some embodiments, the temperature fluctuation is reduced for a stabilized diffuser plate comparing to a fresh diffuser plate.

The cyclic deposition process for some material is temperature sensitive. The increase in temperature causes growth rate to increase, such that the thickness of deposited thin film may be less uniform. When the temperature at the diffuser plate is too high, the atomic layer deposition may at least partially become a chemical vapor deposition as the precursors may react at or around the diffuser plate.

The inventors have found that, in some embodiments, a fresh diffuser plate has a relatively low emissivity. The emissivity of the diffuser plate may increase with the ongoing deposition cycles in an ALD process. After the diffuser plate goes through the stabilization process and reaches a relatively stable status and becomes a stabilized diffuser plate, the emissivity becomes stable until a cleaning process, such as a dry cleaning or wet cleaning process, starts. As illustrated in FIG. 2B, after each time the diffuser plate is cleaned or a new diffuser plate is used, there will be a seasoning period when the growth rate per cycle (GPC) is not stable. During the seasoning period, the GPC decreases with the increase of number of deposition cycle and reaches a stable rate when a diffuser plate goes from a fresh to a stabilized status. The emissivity of the diffuser plate increases during the seasoning period until the diffuser plate reaches the stabilized status. In some embodiments, the decrease of the GPC may indicate that the temperature of the substrate has decreased. The inventors have found that the reduction in temperature can be attributed to the formation of a thin film on the diffuser plate, which increases the emissivity of the diffuser plate.

As the diffuser plate may comprise a plurality of holes for gas distribution, the holes in a diffuser plate have a high emissivity value of about 0.8 and a low reflectivity value of 0.2. The outer surface of the fresh diffuser plate has a low emissivity value of about 0.1 and a high reflectivity value of about 0.9. Thus, there is a large emissivity difference between the holes and surface of a fresh diffuser plate. After a diffuser plate is stabilized, the surface of the stabilized diffuser plate has a higher emissivity value and a lower reflectivity value comparing to the surface of a fresh diffuser plate. Thus, there is a smaller emissivity difference between the holes and surface of a stabilized diffuser plate comparing to that of a fresh diffuser plate. The large emissivity difference between the surface and holes of a fresh diffuser plate may require longer seasoning period for the diffuser plate to reach a stabilized status, which decreases the productivity.

As discussed above, the growth rate of a deposited thin film may be at least partially related to the deposition temperature, and one source of heat that causes variation of the process temperature is the reflection of radiation from the diffuser plate back to the wafer substrate. Such reflection of radiation from the diffuser plate to the wafer substrate may be caused by the low emissivity of a fresh diffuser plate, the emissivity mismatch between the wafer (or the deposited material) and the diffuser plate, and/or the emissivity mismatch between the fresh surface of a diffuser plate and the holes of a diffuser plate. Thus, there is a need to increase the emissivity of the diffuser plate or to match the emissivity value of the diffuser plate to that of the wafer or the material to be deposited.

As the deposition in an ALD process is performed in a monolayer-by-monolayer fashion and can be precisely controlled down to the monolayer level, accurate temperature control can be significantly more important relative to other deposition techniques such as chemical vapor deposition or physical vapor deposition, and temperature fluctuation should be controlled much more carefully for ALD deposition processes. In addition, to reduce cycle time, the volume above the substrate may be relatively smaller in some ALD reactors. As a result, the distance between a diffuser plate the substrate may be relatively smaller in ALD reactors. Thus, it can be relatively more important to have a diffuser plate having a uniform emissivity across the surface of the diffuser plate, especially on the surface directly facing the substrate or the susceptor in the deposition chamber.

Based on the above observations, the inventors have discovered that it is advantageous to fabricate a diffuser plate having a laser-textured surface, such that the emissivity of the surface of a fresh diffuser plate starts out relatively high and stays relatively high with smaller drift in emissivity over time. The gas diffuser plate having the laser-textured surface has an emissivity higher than that of the gas diffuser plate without the laser-textured surface. As illustrated in FIG. 2C, with the laser-textured surface, a fresh diffuser plate may be in a stabilized status and have a stable emissivity and no temperature fluctuation from the beginning of the deposition, such that deposition process becomes more efficient as the time to stabilize the diffuser plate is eliminated or reduced.

Another concern for a vapor deposition process is particle contamination generated from the diffuser plate during the deposition process. During a vapor deposition process, the material to be deposited may be formed not only on a wafer, but also on the inner wall of the deposition chambers, the surfaces of a diffuser plate, or any other surfaces the precursors can reach. In addition, the byproducts may also be formed on those surfaces. In some embodiments, the diffuser plate may be cleaned in a cleaning process. In some embodiments, the cleaning process may be a wet cleaning process or a dry-cleaning process. In some embodiments, a cleaning gas may be supplied into the deposition chamber to remove the deposited materials or byproducts from the surfaces other than the wafer. In some embodiments, the cleaning gas may be corrosive. In some embodiments, the cleaning gas may comprise NF₃, F₂, Ar, ClF₃, or combinations thereof. Under some circumstances, the cleaning gas may be corrosive or erosive to the diffuser plate. In some other circumstances, the precursors used for deposition, such as TiCl₄, NH₃, SiH₂Cl₂ (DCS), SiH₄ (Silane), HCl, NHCl₄, Adducts, may be corrosive to the diffuser plate. Accordingly, the diffuser plate may be corroded or eroded by certain chemicals supplied to or generated during the deposition process. In those circumstances, the corrosion of the diffuser plate may generate particles and fall from the diffuser plate during deposition process, such that the deposited thin film may be contaminated. In addition, it is especially important to reduce the particle generated from the surface of the diffuser plate facing the substrate or susceptor when present in the deposition chamber because the particles generated from such surface may be directly incorporated in the deposited film during processing. Thus, there is a need for a corrosion-resistant coating layer for a diffuser plate surface to reduce the particles generated during the cleaning or corrosion of the diffuser plate by cleaning gas, precursors, or any chemicals generated during processing.

### C. LASER-TEXTURED SURFACE FOR A DIFFUSER PLATE FOR A SHOWERHEAD ASSEMBLY

To address, among other things, the problem of temperature fluctuation due to radiosity of the deposition system and particle contamination, a gas diffuser plate according to various embodiments having a laser-textured surface configured to control emissivity is disclosed. In some embodiments, the diffuser plate may comprise a laser-textured surface. In some embodiment, the laser-textured surface of the diffuser plate may be configured to directly face the substrate or susceptor when the diffuser plate is present in the deposition chamber. In some embodiments, only the surface of the diffuser plate facing the substrate or susceptor may be laser textured. In some embodiments, only the surface of the diffuser plate is laser-textured and the deposition chamber does not comprise other laser-textured surfaces.

In some embodiments, a protective top-coating layer configured to reduce particle contamination forms on the laser-textured surface. In some embodiments, the laser-textured surface may comprise microstructures. In some embodiments, the microstructures of the laser-textured surface may be formed by laser-processing. In some embodiments, the protective top-coating layer is formed by atomic layer deposition (ALD). In some embodiments, the thickness of the protective coating layer is uniform throughout the protective top-coating layer.

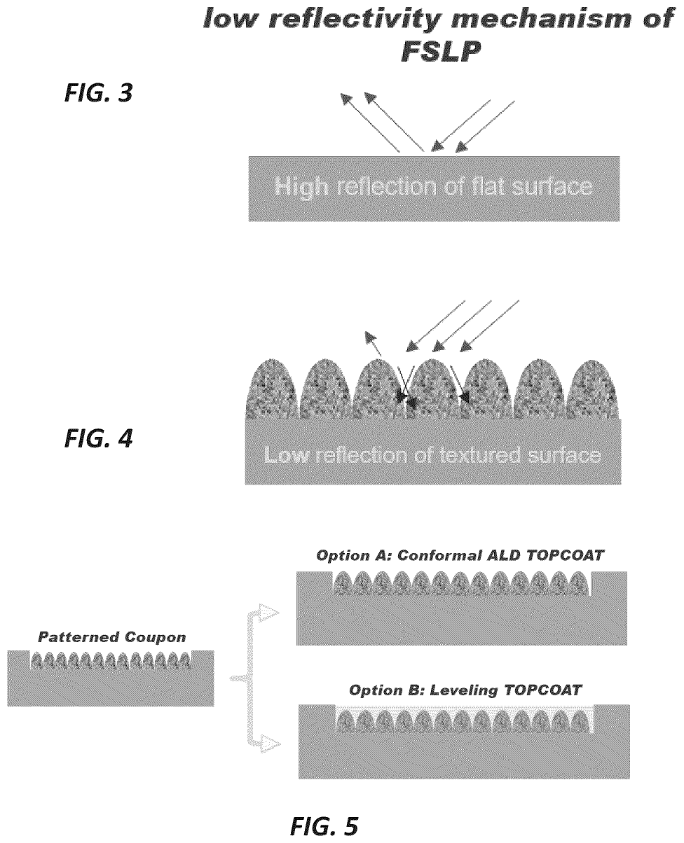

In some embodiments, the laser-textured surface is formed by first processing the substrate with a laser. In some embodiments, a protective top-coating layer is then formed on the laser-textured surface. FIG. 3 schematically illustrates a flat surface of a substrate with high reflectivity. FIG. 4 schematically illustrates a substrate with a layer of microstructures. In some embodiments, the microstructures may have a dome or pillar shape, or any other shape. In some embodiments, the microstructures may be formed by laser-processing. In some embodiments, laser-processing may comprise removing material from certain areas of the substrate with a laser. In some embodiments, the substrate illustrated in FIG. 4 is a substrate having a laser-textured surface. The layer of microstructures on the substrate may decrease the amount of light been reflected from the substrate, such that the emissivity of the substrate may be increased comparing to a substrate having a flat surface. FIG. 5 schematically illustrates two options of the morphology of the protective top-coating layer to protect the layer of microstructures from corrosion and reduce the particle generation. As illustrated in FIG. 5, one option is to form a conformal top coating layer on the surface of each microstructure. Another option is to form a leveled top coating layer on top of the microstructures by filling the areas where the material is removed from the substrate during the laser processing, such that the surface of the top coating layer is approximately at the same level as the substrate surface before laser processing.

### Laser-Textured Surface

In some embodiments, a substrate may be processed by a laser to form a laser-textured surface on the substrate. In some embodiments, the substrate comprises aluminum. In some embodiments, the laser processing may comprise laser ablation. In some embodiments, the laser processing may comprise removing material from certain areas of a substrate with a laser. In some embodiments, the laser processing may comprise femtosecond laser surface processing (FSLP). In some embodiments, the laser processing may be performed in the ambient air. In some embodiments, the laser processing may be performed in a shielding gas. In some embodiments, the shielding gas may comprise an inert gas. In some embodiments, the laser-processed substrate having a laser-textured surface may have an emissivity higher than an emissivity of the substrate before being processed by a laser. In some embodiments, the emissivity value of the laser-processed substrate may be at least partially related to the parameters of the laser. In some embodiments, the parameters of the laser may include power density, frequency, processing speed, and other relevant parameters. In some embodiments, the processing parameters may result in different emissivity values of the laser-processed substrate. In some embodiments, the resulted emissivity value may be at least partially related to the laser power density. In some embodiments, the resulted emissivity value may be at least partially related to the laser scanning speed. In some embodiments, the resulted emissivity value may be at least partially to the type of optics used for generating the laser.

In some embodiments, the laser-textured surface may improve the emissivity of the substrate when there is no such laser-textured surface. In some embodiments, the emissivity of the laser-textured surface may be selected according to needs. In some embodiments, the emissivity may be selected at least partly related to the emissivity of the material to be deposited on the wafer. In some embodiments, the emissivity of substrate having such a laser-textured surface may be about 0.05 to about 0.9, about 0.2 to about 0.8, about 0.2 to about 0.7, about 0.4 to about 0.9, may be about 0.9, 0.85, 0.8, 0.75, 0.7, 0.65, 0.6, 0.55, 0.5, 0.45, 0.4, 0.35, 0.3, 0.25, 0.2, 0.15, or any number in a range defined by any of these values. In some embodiments, an emissivity of about 0.4 to about 0.65 may be of interest for the application of a gas diffuser plate. The emissivity values may be measured at a wavelength greater than 2 μm, 5 μm, 10 μm, 15 μm, 20 μm or 25 μm, or a value in in a range defined by any of these values, e.g., about 2-10 μm. The inventors found that the surface of the gas diffuser plate having the emissivity values measured at wavelengths as disclosed herein, for instance an emissivity of about 0.4 to about 0.65 measured at 2-10 μm, may provide particularly low temperature fluctuation at the substrate and high wafer-to-wafer deposition process stability.

In some embodiments, the laser-textured surface may comprise a layer of microstructures. In some embodiments, a microstructure may refer to a structure having at least one characteristic dimension within the range of 1 μm to 1000 μm. In some embodiments, the characteristic dimension may include height, width, diameter, full-width at half maximum (FWHM), peak-to-valley height, etc. In some embodiments, the microstructure may comprise a shape of dome, pillar, mound, hemisphere, or any other shape. In some embodiments, the microstructures may comprise an average peak-to-valley height of about 1 μm to about 50 μm, may be about 1.5 μm, 2 μm, 2.5 μm, 3 μm, 3.5 μm, 4 μm, 4.5 μm, 5 μm, 5.5 μm, 6 μm, 6.5 μm, 7 μm, 8 μm, 9 μm, 10 μm, 15 μm, 20 μm, 25 μm, 30 μm, 35 μm, 40 μm, 45 μm, 50 μm, or any number in a range defined by any of these values, for example, about 1 μm to 10 μm, 1 μm to 5 μm, 2 μm to 5 μm. The peak-to-valley height of the microstructure may refer to a height between a topmost point of the microstructure and the lowest point adjacent to the microstructure, such as the lowest point of a region that may be described as a valley nearest to the microfeature. In some embodiments, the microstructure may comprise an average width of about 1 μm to about 50 μm, may be about 1 μm, 2 μm, 3 μm, 4 μm, 5 μm, 6 μm, 7 μm, 8 μm, 9 μm, 10 μm, 11 μm, 12 μm, 13 μm, 14 μm, 15 μm, 20 μm, 25 μm, 30 μm, 35 μm, 40 μm, 45 μm, 50 μm, or any number in a range defined by any of these values, for example, about 1 μm to 20 μm, 1 μm to 10 μm. In some embodiments, a width of a microstructure may refer to the distance between the lowest point of two nearest valleys in one direction of the microstructure. In some embodiments, the width may be measured at bases of the microstructures.

In some embodiments, the laser-textured surface may be isotropic. In some embodiments, the laser-textured surface may comprise an isotropic roughness in all directions. In some embodiments, the laser-textured surface may have a uniform roughness. In some embodiments, a uniform roughness may refer to a uniform roughness in a certain direction. In some embodiments, a uniform roughness of the laser-textured surface in a certain direction may refer to that the difference between an arithmetic average roughness Rₐ in a first distance in the certain direction and an Rₐ in a second distance in the certain direction may be less than about 100%, about 90%, about 80%, about 70%, about 60%, about 50%, about 40%, about 30%, about 20%, or about 10%, or any number in a range defined by any of these values. In some embodiments, the first distance and the second distance may be randomly selected along the same direction and may include same number of microstructures. In some embodiments, a uniform roughness may refer to that the microstructures of the laser-textured surface have similar peak-to-valley heights, such as within 50% to 200% of the average peak-to-valley height. In some embodiments, a uniform roughness of the laser-textured surface may refer to that the laser-textured surface may have similar roughness in all directions. In some embodiments, a uniform roughness of the laser-textured surface may refer to that the laser-textured surface has similar roughness in the laser-scanning direction (referred to as “X direction”) and the direction perpendicular to the laser-scanning direction (referred to as “Y direction”). In some embodiments, the difference between the roughness in an X direction and the roughness in a Y direction may be less than about 100%, about 90%, about 80%, about 70%, about 60%, about 50%, about 40%, about 30%, about 20%, or about 10%, or any number in a range defined by any of these values.

In some embodiments, the emissivity may be at least partially related to the value of roughness, such as Rₛₖ. Rₛₖ refers to skewness, or measure of asymmetry of the profile about the mean line. A negative value of Rₛₖ indicates that the surface is made up of valleys, whereas a surface with a positive skewness is said to contain mainly peaks and asperities. Skewness uses the cube of the root mean square deviation to display the dimensionless cube of the sampling length Z(x).

$${R}_{sk} = \frac{1}{{mnR}_{q}^{3}} {\sum }_{k = 0}^{m - 1} {\sum }_{l = 0}^{n - 1} {( Z ( {x}_{k} , {y}_{l} ) - μ )}^{3}$$

In some embodiments, the emissivity may be at least partially related to the value of Rₛₖ. In some embodiments, a higher Rₛₖ may indicate a lower emissivity and a higher reflectivity of the laser-textured surface.

The inventors have found that, due to various factors, different areas of the substrate may be affected at different degrees by the radiation from the diffuser plate. Accordingly, a variation in emissivity across the diffuser plate may purposely be introduced. To address these circumstances, in some embodiments, the emissivity values of a laser-textured surface may be purposely varied across the area such that different emissivity values are imparted to different areas or regions of the laser-textured surface. In some embodiments, the laser-textured surface may comprise different degrees of texturing, which may result in different emissivity values. In some embodiments, different degrees of texturing may correspond to different laser processing parameters. In some embodiments, different degrees of texturing may correspond to different roughness, such as different Rₛₖ values. In some embodiments, the laser-textured surface may comprise a plurality of rings with a same center, each ring may have substantially the same degree of texturing within the ring and different degrees of emissivity comparing to other rings. In some embodiments, the emissivity of each ring may be within about 70% to about 130% of the mean emissivity value of the whole laser-textured surface. In some embodiments, the emissivity value of a ring may be at least 10% different from the neighboring ring. In some embodiments, the different emissivity of different areas or rings may correspond to different temperature feedback.

In some embodiments, each microstructure of the laser-textured surface may comprise a metal core integrally protruding from the substrate, and may further comprise a layer of oxide formed on the metal core. In some embodiments, the metal oxide layer may be much thinner than the metal core. In some embodiments, the average height of the metal cores may be about 1 μm to about 50 μm, may be about 1.5 μm, 2 μm, 2.5 μm, 3 μm, 3.5 μm, 4 μm, 4.5 μm, 5 μm, 5.5 μm, 6 μm, 6.5 μm, 7 μm, 8 μm, 9 μm, 10 μm, 15 μm, 20 μm, 25 μm, 30 μm, 35 μm, 40 μm, 45 μm, 50 μm, or any number in a range defined by any of these values, for example, about 1 μm to 10 μm, 1 μm to 5 μm, 2 μm to 5 μm. In some embodiments, the height of the metal core may refer to the height between the topmost point of the metal core and the lowest point adjacent to the metal core for a certain microstructure. In some embodiments, the average thickness of the metal oxide layer may be about 10 nm to about 1 μm, may be about 10 nm, 20 nm, 25 nm, 30 nm, 50 nm, 60 nm, 70 nm, 80 nm, 90 nm, 100 nm, 150 nm, 200 nm, 250 nm, 300 nm, 350 nm, 400 nm, 450 nm, 500 nm, 600 nm, 700 nm, 800 nm, 900 nm, 1000 nm, or any number in a range defined by any of these values. In some embodiments, the microstructure may comprise a layer of nanostructures formed on the surface of each microstructure. In some embodiments, the nanostructures may comprise nanoparticles or aggregation of nanoparticles. In some embodiments, the nanostructures comprise an average size of about 0.1 nm to 500 nm, may be about 0.1 nm, 0.2 nm, 0.5 nm, 1 nm, 1.5 nm, 2 nm, 3 nm, 4 nm, 5 nm, 6 nm, 7 nm, 8 nm, 9 nm, 10 nm, 15 nm, 20 nm, 30 nm, 40 nm, 50 nm, 60 nm, 70 nm, 80 nm, 90 nm, 100 nm, 150 nm, 200 nm, 250 nm, 300 nm, 350 nm, 400 nm, 450 nm, 500 nm, or any number in a range defined by any of these values, such as 0.1 nm to 50 nm, 0.1 nm to 100 nm, 0.1 nm to 150 nm. In some embodiments, the size of a nanostructure may refer to the largest length in any direction. In some embodiments, the metal oxide layer of the microstructures may be an aggregation of the nanostructures. In some embodiments, the nanostructures may comprise amorphous metal oxide, such as amorphous aluminum oxide. In some embodiments, the nanostructures may comprise aluminum oxide. In some embodiments, the nanostructures may be not densely packed around the metal core.

In some embodiments, the laser-textured surface may be formed by femtosecond laser processing (FSLP). In some embodiments, the laser processing may use a laser having a scanning speed of about 50 mm/s to 500 mm/s, may be about 50 mm/s, 75 mm/s, 100 mm/s, 125 mm/s, 150 mm/s, 200 mm/s, 250 mm/s, 300 mm/s, 350 mm/s, 400 mm/s, 500 mm/s, or any number in a range defined by any of these values. In some embodiments, with other parameters being the same, a slower scanning speed may result in a laser-textured surface having a higher emissivity. In some embodiments, the laser processing may use a laser having a power of about 1 W to about 50 W, may be about 2 W, 3 W, 4 W, 5 W, 6 W, 7 W, 8 W, 9 W, 10 W, 11 W, 12 W, 13 W, 14 W, 15 W, 16 W, 17 W, 18 W, 19 W, 20 W, 25 W, 30 W, 35 W, 40 W, 45 W, or 50 W, or any number in a range defined by any of these values, such as 1W-10 W, 2 W-6 W, etc. In some embodiments, with other parameters being the same, a higher the laser power may result in a laser-textured surface having a higher emissivity. In some embodiments, the laser may have a wavelength of 1030 nm. In some embodiments, the laser may have a frequency of about 100 kHZ to 1000 kHz, may be about 100 Hz, 150 Hz, 200 Hz, 250 Hz, 300 Hz, 350 HZ, 400 Hz, 500 Hz, 600 Hz, 700 Hz, 800 Hz, 900 Hz, 1000 Hz, or any number in a range defined by any of these values. In some embodiments, the laser is a pulsed laser. In some embodiments, the laser processing may use a laser having a pulse duration of about 0.1 to 50 ps, may be about 0.1 ps, 0.3 ps, 0.5 ps, 1 ps, 5 ps, 10 ps, 15 ps, 20 ps, 25 ps, 30 ps, 40 ps, 50 ps or any number in a range defined by any of these values. In some embodiments, the laser processing may use a laser having a pulse energy of about 10 μJ to about 500 μJ, may be about 10 μJ, 15 μJ, 20 μJ, 25 μJ, 30 μJ, 25 μJ, 40 μJ, 45 μJ, 50 μJ, 55 μJ, 60 μJ, 65 μJ, 70 μJ, 75 μJ, 80 μJ, 85 μJ, 90 μJ, 95 μJ, or 95 μJ, 100 μJ, 150 μJ, 200 μJ, 250 μJ, 300 μJ, 400 μJ, or 500 μJ, or any number in a range defined by any of these values, such as 15 μJ to 30 μJ, 25 μJ to 30 μJ. In some embodiments, the cross section of the laser beam may be a circle. In some embodiments, the diameter of the circular laser beam may be about 5 μm to about 500 μm, may be about 5 μm, 10 μm, 15 μm, 20 μm, 25 μm, 30 μm, 35 μm, 40 μm, 45 μm, 50 μm, 55 μm, 60 μm, 65 μm, 70 μm, 75 μm, 80 μm, 85 μm, 90 μm, 95 μm, 100 μm, 110 μm, 120 μm, 130 μm, 140 μm, 150 μm, 160 μm, 170 μm, 180 μm, 190 μm, 200 μm, 250 μm, 300 μm, 350 μm, 400 μm, 450 μm, 500 μm, or any number in a range defined by any of these values, such as about 10 μm to about 300 μm, about 10 μm to about 100 μm, about 20 μm to about 100 μm. In some embodiments, the pulsed energy density of the laser beam may be about 0.01 J/cm² to about 20,000 J/cm².

In some embodiments, the laser processing may comprise laser line scanning. In some embodiments, the laser beam may scan the substrate in consecutive lines. In some embodiments, the distance between two consecutive lines may be less than the diameter of the laser beam. In some embodiments, the distance between the two consecutive lines may be about 10% to 99% of the diameter of the laser beam, for example, about 10%, 25%, 30%, 35%, 40%, 45%, 50%, 55%, 60%, 65%, 70%, 75%, 80%, 85%, 90%, 95%, 99%, or any of the range therebetween. In some embodiments, a laser beam may overlap with the laser beam in adjacent line scanning. In some embodiments, the area where the laser beam overlaps (referred to as overlapping region) may cause the formation of stripes of laser scanning marks in the overlapped region. In some embodiments, the regions between the adjacent stripes of laser scanning marks are regions where the laser beam does not overlap with the laser beam in adjacent scanning line, and are referred to as non-overlapping regions.

In some embodiments, the laser-textured surface comprises stripes of laser scanning marks. In some embodiments, the stripes extend in a direction parallel to a laser scanning direction characteristic of laser texturing. In some embodiments, the stripes correspond to regions where laser scanning lines overlap. In some embodiments, the laser scanning marks comprise microstructures having substantially different sizes or textures relative to sizes or textures of microstructures in regions of the laser-textured surface between adjacent stripes of laser scanning marks. In some embodiments, the microstructures in the overlapped region may have a size, width, or peak-to-valley height smaller than those of the microstructures in the non-overlapping region.

### Protective Top-Coating Layer

Under some circumstances, the laser-processed substrate having the laser-textured surface and the chamber environment may need to be mutually protected from each other due to various factors including, e.g., corrosive chemistry, process contamination and particle generations. In addition, the laser-textured surface may be easy to be corroded or etched as the nanostructures on the surface are not densely packed. The inventors have further discovered that these concerns, among others, can be addressed, for particular laser-textured substrate described herein, by introducing a coating for a diffuser plate for cyclic deposition processes. In some embodiments, the coating is a protective top-coating layer having a high corrosion resistance against the precursors, by-products, or any other chemicals generated or used in the deposition chamber during the cyclic deposition process. In some embodiments, the protective top-coating may comprise a corrosion-resistant material. In some embodiments, the protective top-coating layer may have a high corrosion resistance against the cleaning gas. In some embodiments, the protective top-coating layer may have a high corrosion resistance against NF₃, F₂, Ar, ClF₃, or combinations thereof.

In some embodiments, the protective top-coating layer may be transparent or translucent. In some embodiments, the protective top-coating layer may comprise a ceramic base coating. In some embodiments, the protective top-coating layer may comprise aluminum oxide. In some embodiments, the protective top-coating comprises Al₂O₃. In some embodiments, the protective top-coating layer may comprise yttrium aluminum garnet (YAG). In some embodiments, the protective top-coating layer may comprise crystalline. In some embodiments, the protective top-coating layer may have a thickness of about 100 nm to about 10 μm, may be about 100 nm, 200 nm, 500 nm, 700 nm, 900 nm, 1 μm, 1.5 μm, 2 μm, 2.5 μm, 3 μm, 5 μm, 7 μm, 9 μm, 10 μm, or any number in a range defined by any of these values.

In some embodiments, the protective top-coating may not substantially change the emissivity of the substrate. In some embodiments, depositing a protective top-coating coating on the laser-textured surface of a diffuser plate may change the emissivity value of the diffuser plate. In some embodiments, the emissivity value of a diffuser plate may be increased after depositing the protective top-coating coating. In some embodiments, the emissivity value of a diffuser plate may be decreased after depositing the protective top-coating coating. In some embodiments, the emissivity value of a diffuser plate may be decreased by about 0 to about 100%, may be about 1%, about 5%, about 10%, about 15%, about 20%, about 25%, about 30%, about 35%, about 40%, about 50%, about 55%, about 60%, about 65%, about 70%, about 75%, about 80%, about 85%, about 90%, about 95%, about 100%, or any number in a range defined by any of these values, after depositing the protective top-coating coating. In some embodiments, the emissivity value of a diffuser plate may be increased by about 0 to about 100%, may be about 1%, about 5%, about 10%, about 15%, about 20%, about 25%, about 30%, about 35%, about 40%, about 50%, about 55%, about 60%, about 65%, about 70%, about 75%, about 80%, about 85%, about 90%, about 95%, about 100%, or any number in a range defined by any of these values, after depositing the protective top-coating coating.

In some embodiments, the protective top-coating layer may be formed by vapor deposition process, such as an atomic layer deposition (ALD) method. In some embodiments, the protective top-coating coating may be conformal, for example, the thickness of the protective top-coating layer may be about the same throughout the entire protective top-coating layer. In some embodiments, the protective top-coating layer follows the morphology of the microstructures in the laser-textured surface, and does not substantially increase or change the roughness of the laser-textured surface. In some embodiments, the top-protective coating may at least partially fill the valley of the microstructures.

In some embodiments, the protective top-coating is not a conformal layer. In some embodiments, after deposition of the protective top-coating layer, the surface roughness of the diffuser plate may be decreased by less than or less than about 100%, 90%, 80%, 70%, 60%, 50%, 45%, 40%, 35%, 30%, 25%, 20%, 15%, 10%, 5%, or any other percentages. In some embodiments, the protective top-coating layer may substantially fill the valleys of the microstructures. In some embodiments, the protective top-coating layer may fill in the dead volume trapped in the microstructures at locations such as valleys. In some embodiments, the protective top-coating layer may completely fill the gaps and/or valleys among the microstructures and form a flat surface. In some embodiments, the protective top-coating layer and the laser-textured surface have good compatibility.

### D. EXAMPLES

### Example 1—Laser-Textured Surface

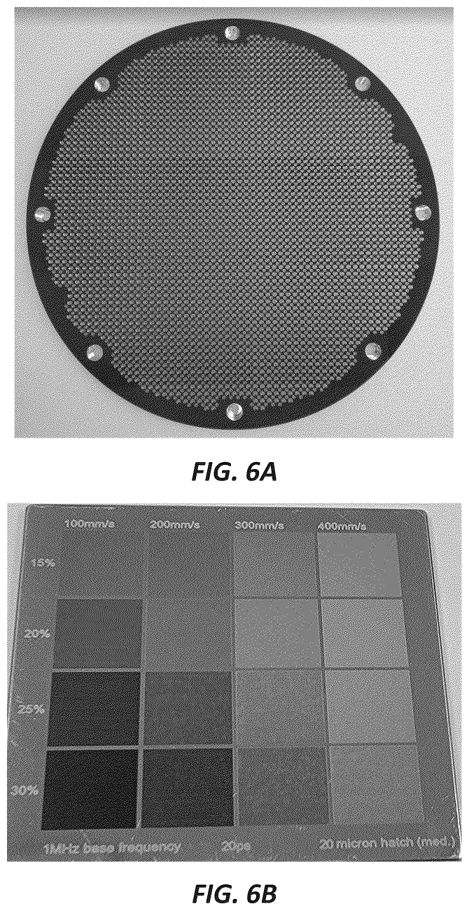

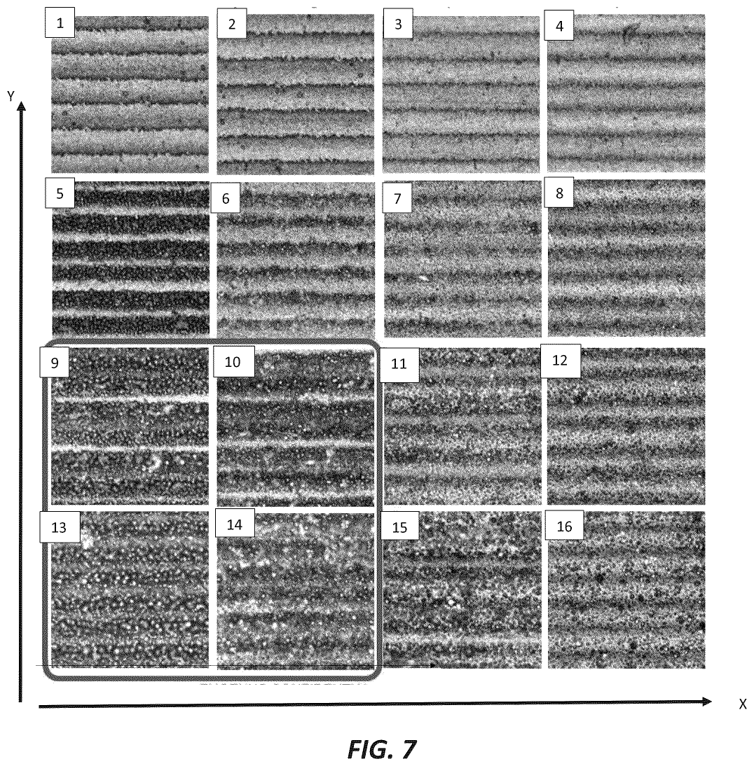

FIG. 6A shows an image of a laser-processed diffuser plate according to some embodiments. As illustrated in FIG. 6A, the surface of the laser-processed diffuser plate is dark comparing to a fresh diffuser plate. FIG. 6B illustrates 16 laser-processed aluminum substrate samples with different laser parameters according to some embodiments. The laser beam has a diameter of 50 μm. The maximum laser power is 20 W and the maximum energy pulse is 100 μJ. FIG. 7 shows microscopic images of the laser-processed aluminum substrate samples in FIG. 6B with a 1000× magnification. The substrate samples were processed by a pulsed laser at a frequency of 200 kHz with a scanning direction along the X direction as illustrated in FIG. 7. Table 1-1 below illustrates the laser processing parameters and the corresponding samples in FIGS. 6B and 7.

TABLE 1-1

| Sample | Laser scanning speed | Laser power | |
|---|---|---|---|
| No. | (mm/s) | (% of 20 W) | Emissivity |
| 1 | 100 | 15% | 0.2 |
| 2 | 200 | 15% | / |
| 3 | 300 | 15% | 0.09 |
| 4 | 400 | 15% | / |
| 5 | 100 | 20% | / |
| 6 | 200 | 20% | 0.24 |
| 7 | 300 | 20% | / |
| 8 | 400 | 20% | 0.04 |
| 9 | 100 | 25% | / |
| 10 | 200 | 25% | 0.39 |
| 11 | 300 | 25% | 0.13 |
| 12 | 400 | 25% | / |
| 13 | 100 | 30% | 0.64 |
| 14 | 200 | 30% | / |
| 15 | 300 | 30% | / |
| 16 | 400 | 30% | 0.07 |

Table 1-2 summarizes the laser processing parameter with the corresponding resulted emissivity of the laser-processed substrate according to some embodiments.

TABLE 1-2

| Laser scanning speed | Laser power | Pulse Energy | |
|---|---|---|---|
| (mm/s) | (W) | (μJ) | Emissivity |
| 75 | 5 | 25 | 0.38 |
| 125 | 5 | 25 | 0.49 |
| 75 | 6 | 30 | 0.36 |
| 100 | 6 | 30 | 0.60 |
| 100 | 3 | 15 | 0.2 |
| 125 | 6 | 30 | 0.52 |
| 200 | 4 | 20 | 0.24 |
| 200 | 5 | 25 | 0.39 |
| 300 | 3 | 15 | 0.09 |
| 300 | 5 | 25 | 0.13 |
| 400 | 4 | 20 | 0.04 |
| 400 | 6 | 30 | 0.07 |

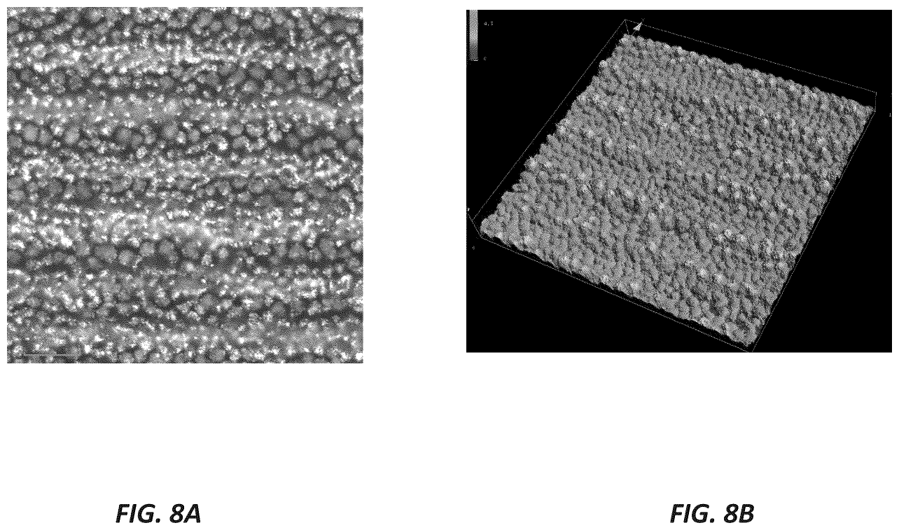

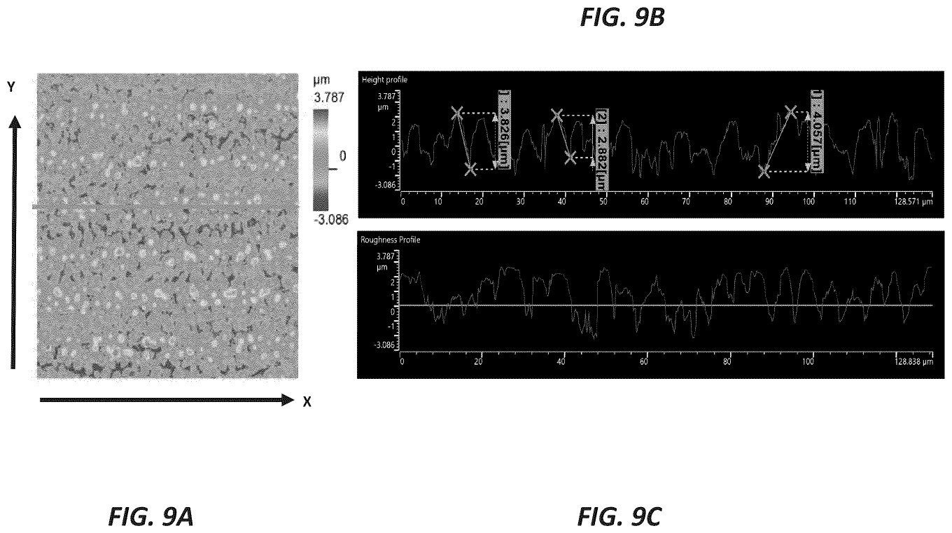

FIG. 8A shows an enlarged microscopic image of a laser-processed substrate according to some embodiments. As illustrated in FIG. 8A, the laser-processed substrate has a laser-textured surface comprising microstructures that are relatively isotropic across the whole substrate. FIG. 8B shows the three-dimensional roughness image of the sample in FIG. 8A. FIG. 9A illustrates the two-dimensional roughness image of the sample as illustrated in FIG. 8A. FIG. 9B illustrates the roughness profile along the scanning route as illustrated in FIG. 9A. FIG. 9C illustrates the roughness profile along the route in the Y direction as illustrated in FIG. 9A. The X direction is scanning direction of the laser. The Y direction is perpendicular to the laser scanning direction. As illustrated in FIG. 9B, the measured peak-to-valley heights of the sample along a X direction is about 3.83 μm, 2.88 μm, 4.06 μm. As illustrated in FIGS. 9B and 9C, the roughness profile along the X and Y directions are similar, which demonstrates that the laser-processed substrate has similar roughness profile in X and Y directions.

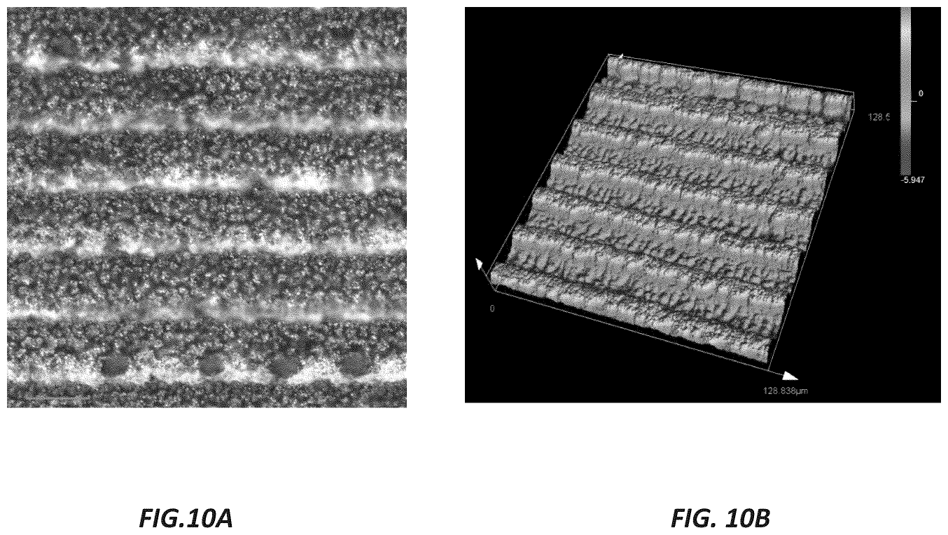

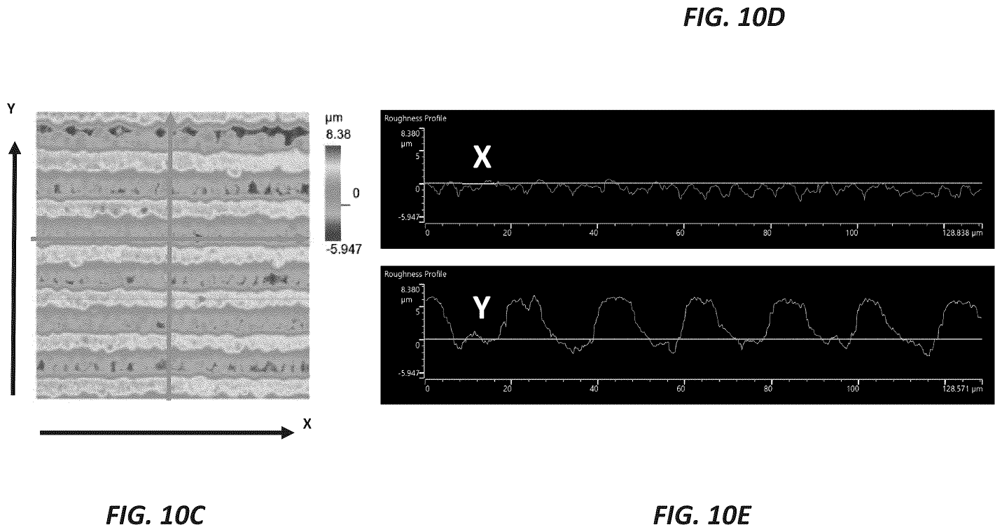

FIG. 10A shows an enlarged microscopic image of a laser-processed substrate according to some embodiments. As illustrated in FIG. 10A, the laser-processed substrate comprises a laser-textured surface having microstructures that are relatively anisotropic in X and Y directions. FIG. 10B shows the three-dimensional roughness image of the sample in FIG. 10A. FIG. 10C illustrates the two-dimensional roughness image of the sample as illustrated in FIG. 10A. FIG. 10D illustrates the roughness profile along the scanning route in X direction as illustrated in FIG. 10C. FIG. 10E illustrates the roughness profile along the scanning route in Y direction as illustrated in FIG. 10C. As illustrated in FIGS. 10D and 10E, the roughness profiles along the X and Y directions are very different. As demonstrated in FIGS. 10B-10E, a relatively large valley is formed between two ridges in Y direction and the roughness profile in X and Y direction are very different, such that the emissivity at different location of the substrate may be different.

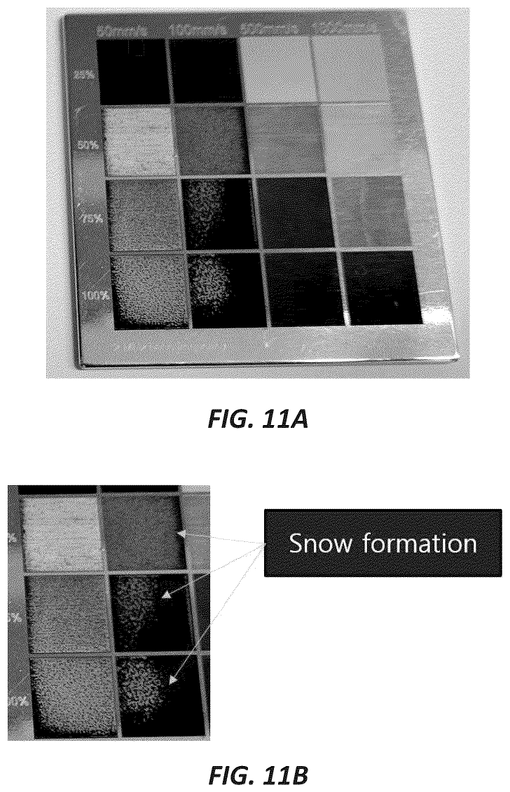

FIG. 11A illustrates the laser-processed substrate samples with different laser processing parameters. As illustrated in FIG. 11A, the surface of some substrate samples became partially or completely white under some processing parameters. Table 2 summarizes the processing conditions and surface morphology for the samples illustrated in FIG. 11A.

TABLE 2

| | | Laser | |
|---|---|---|---|
| Sample | Laser scanning | power (% | |
| No. | speed (mm/s) | of 20 W) | Surface Morphology |
| 17 | 50 | 25% | No formation of white fine crystal |
| 18 | 50 | 50% | Formation of white fine crystal |
| 19 | 50 | 75% | Formation of fine crystal |
| 20 | 50 | 100% | Formation of fine crystal |
| 21 | 100 | 25% | No formation of white fine crystal |
| 22 | 100 | 50% | Formation of white fine crystal |
| 23 | 100 | 75% | Formation of fine crystal |
| 24 | 100 | 100% | Formation of fine crystal |
| 25 | 500 | 25% | No formation of white fine crystal |
| 26 | 500 | 50% | No formation of white fine crystal |
| 27 | 500 | 75% | No formation of white fine crystal |
| 28 | 500 | 100% | No formation of white fine crystal |
| 29 | 1000 | 25% | No formation of white fine crystal |
| 30 | 1000 | 50% | No formation of white fine crystal |
| 31 | 1000 | 75% | No formation of white fine crystal |
| 32 | 1000 | 100% | No formation of white fine crystal |

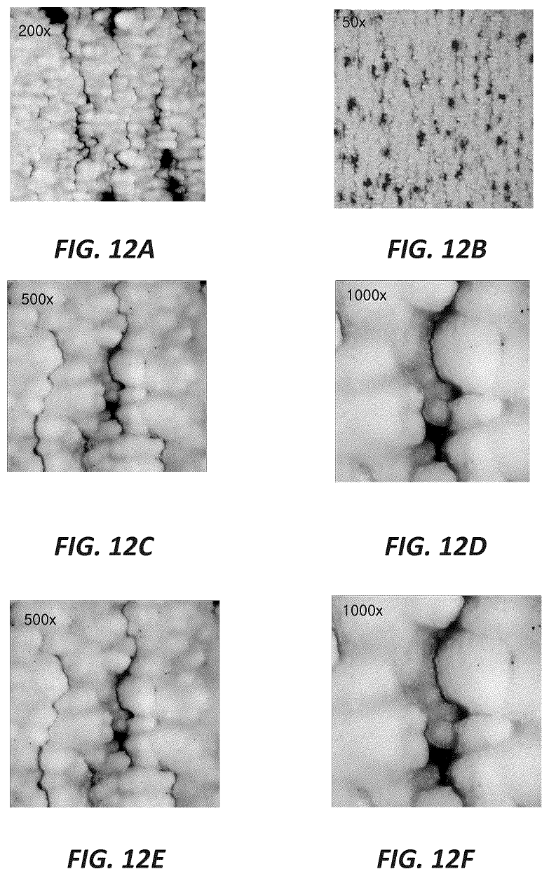

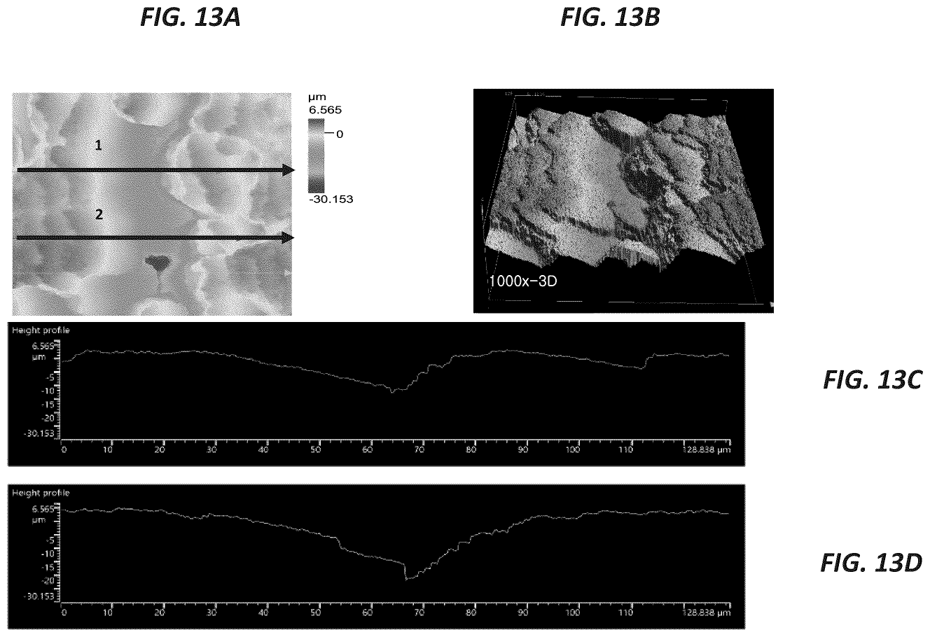

FIG. 11B illustrates an enlarged image for the samples covered by the white structures. The white structures may be fine crystals of hydrolyzed aluminum oxide that are formed under certain conditions such as high power or low scanning speed. Such fine crystals are not desirable as they may peel off and may regenerate particle contamination when the processed substrate is used as a diffuser plate in cyclic deposition. FIGS. 12A-12F show the microscopic images of the sample surface covered by the white crystal structures with different magnifications. FIG. 13A illustrates a 2D roughness profile of a laser-processed sample covered by the white crystal structures with a ×1000 magnification. FIG. 13B illustrates a 3D roughness profile of the laser-processed sample covered by the white crystal structures in FIG. 13A. As illustrated in FIGS. 13A and 131B, random patterns are formed on the surface and do not comprise microstructures similar to those in FIG. 9A. FIGS. 13C and 13D illustrate the roughness profile of the sample along the scanning routes 1 and 2 as shown in FIG. 13A, respectively. FIGS. 13C and 13D confirm that there are no periodic microstructures formed for these samples.

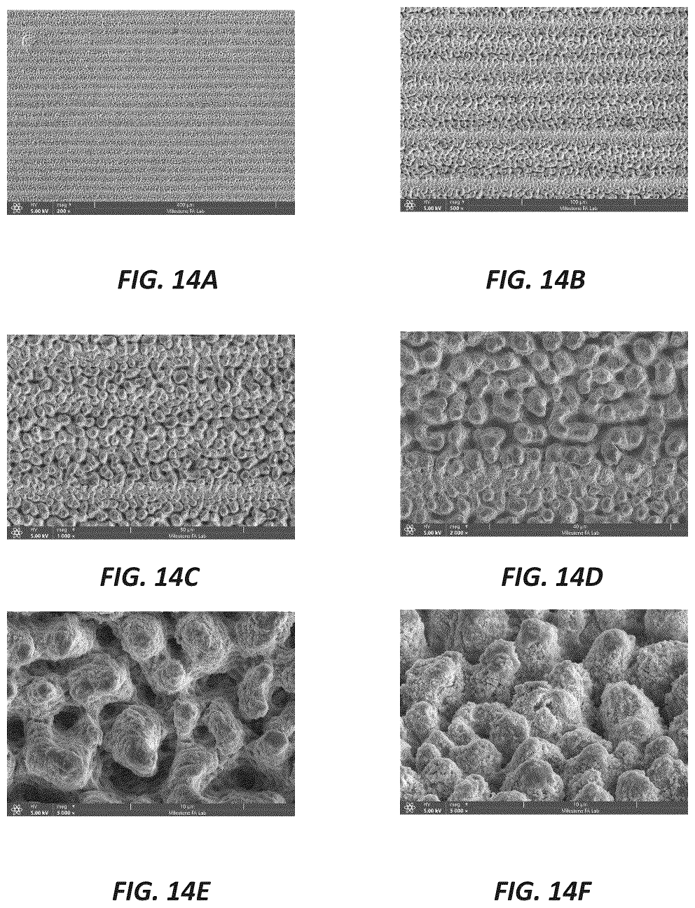

FIGS. 14A-14F illustrate the scanning electron microscope (SEM) images of a laser-processed sample according to some embodiments with different magnifications. The laser-processed sample has an emissivity of 0.5 after laser processing. As illustrated in FIGS. 14A-14F, the microstructures are in a shape of a pillar or dome. As illustrated in FIG. 14B, the laser-textured surface comprises stripes along the laser scanning direction. The stripes may be formed due to the overlap between the laser beams in adjacent lines. As illustrated in FIG. 14C, the sample comprises a layer of substantially uniform microstructures across the whole sample. In addition, the microstructures in the stripes have slightly smaller widths and sizes comparing to the microstructures between the stripes. In addition, the texture and morphology of the microstructures in the stripes are slightly different than the microstructures between the stripes. FIG. 14F illustrates that there are nanosized particles formed on the surface of the microstructures.

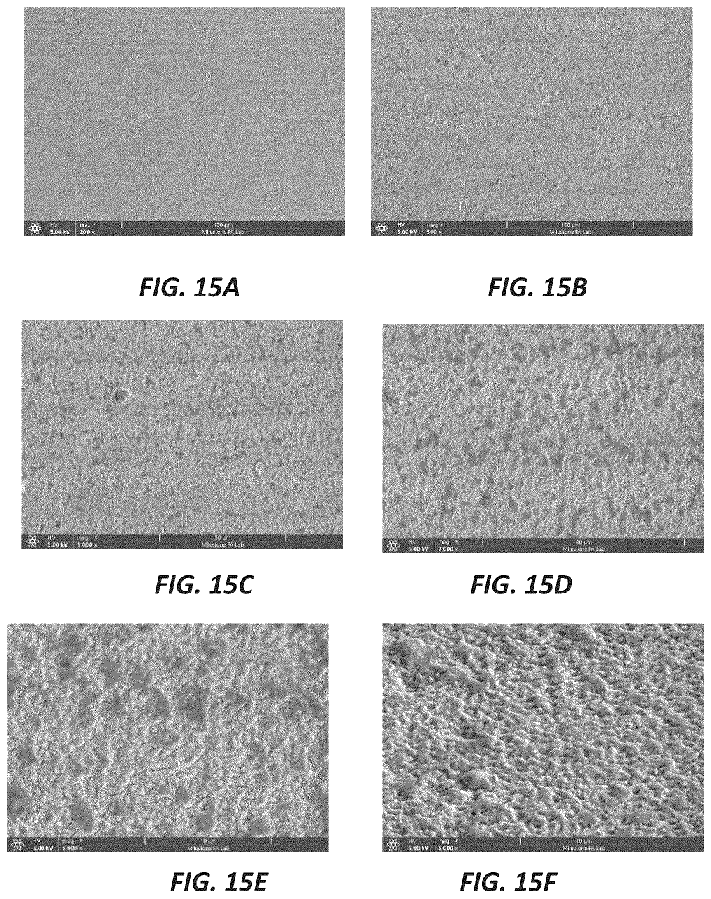

FIGS. 15A-15F illustrate the Scanning electron microscope (SEM) images of a laser-processed sample according to some embodiments. The laser-processed sample has an emissivity of 0.2 after laser processing. As illustrated in FIGS. 15A-15F, the surface of the laser-processed sample comprises interconnected microstructures which are relatively flat and less distinctive comparing to the microstructures illustrated in FIG. 14F.

### Example 2—EDS Analysis of the Microstructures in the Laser-Textured Surface

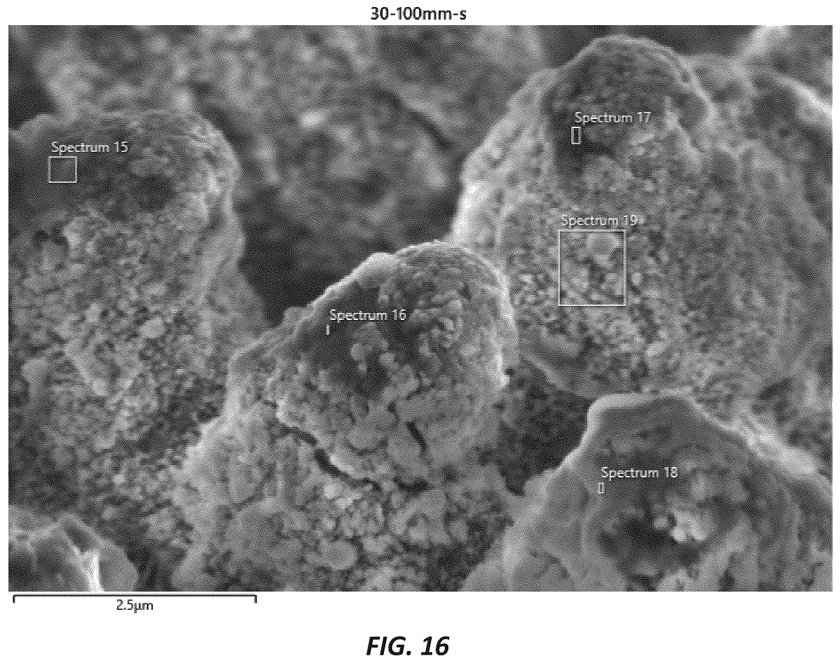

FIG. 16 shows an SEM image of the microstructures formed by the laser processing according to some embodiments. As illustrated in FIG. 16, nanosized structures are formed on the surface of the microstructures. Table 3 summarizes the percentage of elements at each spot as illustrated in FIG. 16 based on the energy-dispersive X-ray spectroscopy (EDS) analysis. The presence of the carbon may be caused by contamination.

TABLE 3

| Spectrum | C | Al | O | N | Mg | V |
|---|---|---|---|---|---|---|
| No. | (at %) | (at %) | (at %) | (at %) | (at %) | (at %) |
| 15 | 40.5 | 31.4 | 26.3 | 1.1 | 0.8 | \ |
| 16 | 20.2 | 42.9 | 34.9 | 1.2 | 0.8 | \ |
| 17 | 7.6 | 59.1 | 29.9 | 1.9 | 1.5 | \ |
| 18 | 32.2 | 27.9 | 31.5 | 1.9 | 0.5 | 6.1 |
| 19 | 4.0 | 67.2 | 25.4 | 2.0 | 1.4 | \ |

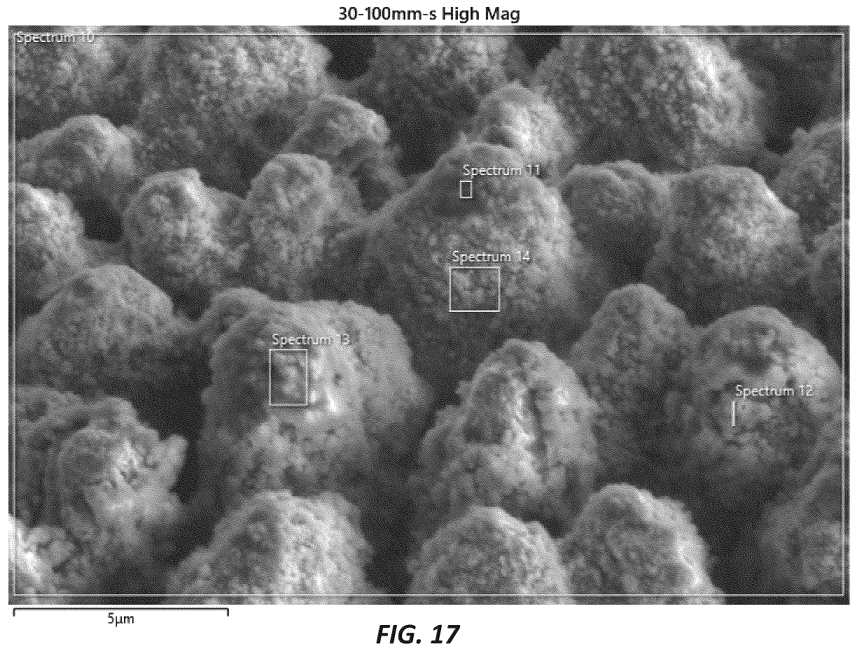

FIG. 17 shows another SEM image of the microstructures formed by the laser processing according to some embodiments. As illustrated in FIG. 17, nanosized structures are formed on the surface of the microstructures. Table 4 summarizes the percentage of elements, excluding carbon, at each spot as illustrated in FIG. 17 based on the EDS analysis.

TABLE 4

| Spectrum | Al | O | N | Mg | |
|---|---|---|---|---|---|
| No. | (at %) | (at %) | (at %) | (at %) | Si(at %) |
| 10 | 66.5 | 30.6 | 2.1 | 0.7 | \ |
| 11 | 55.0 | 42.3 | 1.6 | 1.1 | \ |
| 12 | 43.8 | 51.6 | 3.3 | 1.0 | 0.3 |
| 13 | 41.1 | 55.9 | 2.2 | 0.8 | \ |
| 14 | 59.8 | 35.0 | 4.2 | 0.9 | \ |

As illustrated by the EDS analysis of the samples in FIGS. 16 and 17, the nanostructures on the surface comprise mostly aluminum and oxide, which demonstrates that the nanostructures formed on the surface of the microstructures comprise aluminum oxide, such as Al₂O₃.

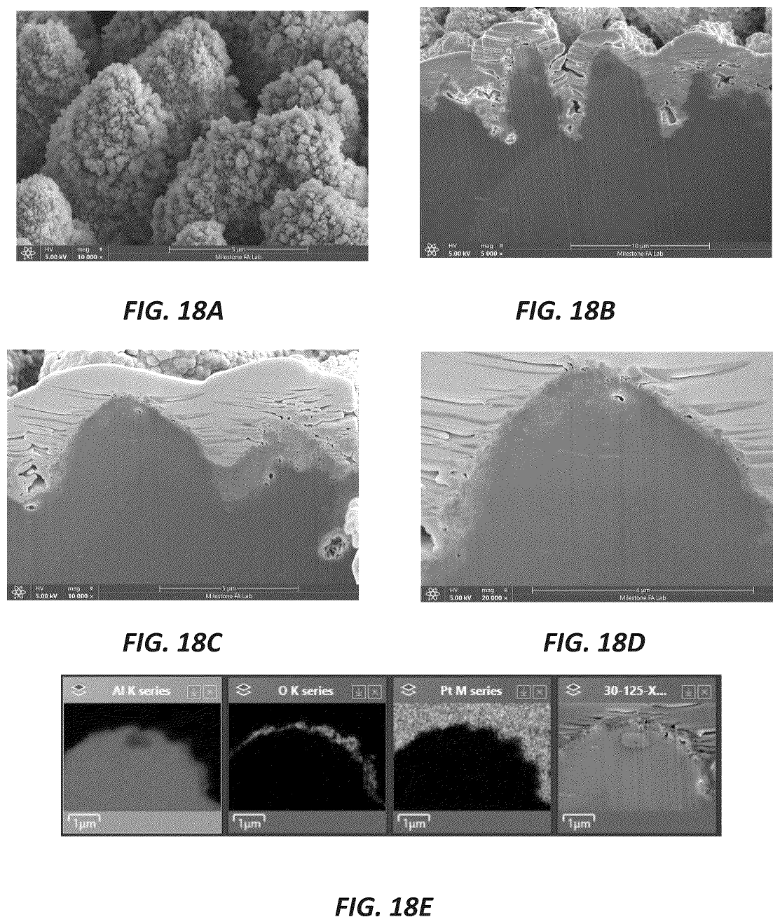

FIG. 18A illustrates an SEM image of a laser-textured surface according to some embodiments with ×10000 magnification. FIGS. 18B-18D show the SEM images of the cross section cut with focused ion beam (FIB) in a X direction (laser-scanning direction). as illustrated in FIG. 18B, the laser-textured surface comprises a plurality of microstructures having similar peak-to-valley heights in X direction. FIG. 18E shows the elemental analysis of a cross section of one microstructure. As illustrated in FIG. 18E, the microstructure comprises a core composing of metal aluminum. In addition, the microstructure comprises a layer on the core, the layer comprises Al and O. The Pt layer on the surface was formed in the FIB process. Thus, as illustrated in FIGS. 18A-18E, the microstructure formed by the laser processing comprises an aluminum core integrally protruding from the substrate, and further comprises a layer of aluminum oxide formed on the aluminum core.

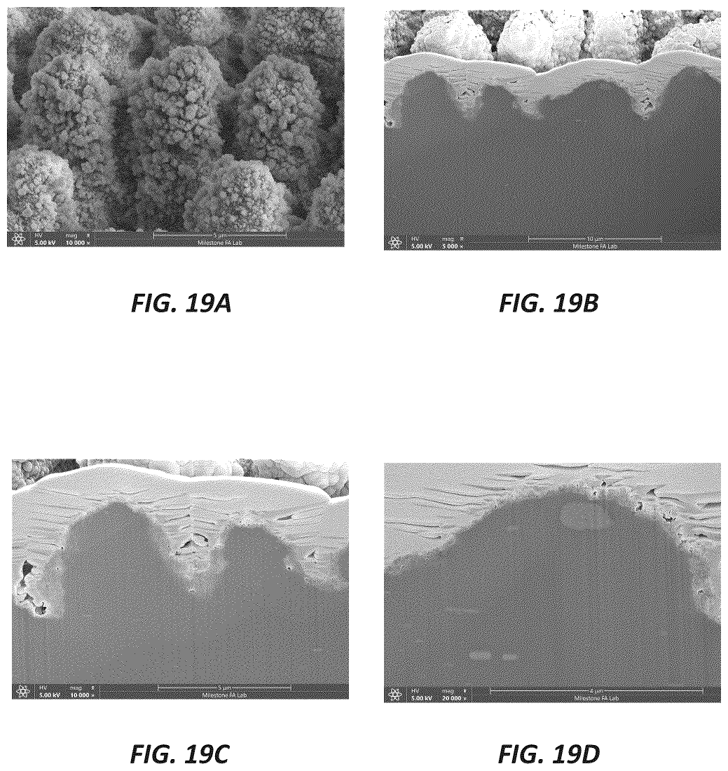

FIG. 19A illustrates an SEM image of a laser-textured surface according to some embodiments with ×10000 magnification. FIGS. 19B-19D show the SEM images of the cross section cut with FIB in a Y direction (perpendicular to the laser-scanning direction). As illustrated in FIGS. 19B-19C, the laser-textured surface comprises a plurality of microstructures having similar peak-to-valley heights in Y direction.

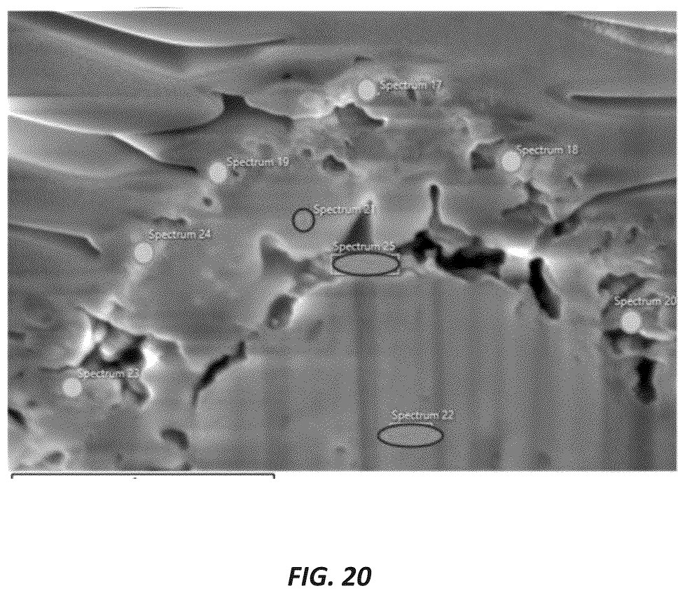

FIG. 20 illustrates different spots on the cross section of the microstructures for elemental analysis. Table 5 summarizes the percentage of elements at each spot as illustrated in FIG. 20 based on the EDS analysis. The EDS analysis of different spots illustrates that the spots on the surface of the microstructure have high content of carbon, and the spots towards the core of the microstructures comprise low carbon content. Such high carbon content may be caused by carbon trapped on the surface of the microstructures due to laser processing.

TABLE 5

| Spectrum | Al | O | C | N | Mg | F |
|---|---|---|---|---|---|---|
| No. | (at %) | (at %) | (at %) | (at %) | (at %) | (at %) |
| 17 | 58.1 | 33.6 | 6.9 | 1.4 | \ | \ |
| 18 | 52.8 | 28 | 18.3 | 0.8 | \ | \ |
| 19 | 45.7 | 37.9 | 15.7 | 0.7 | \ | \ |
| 20 | 57.5 | 28.8 | 12.1 | \ | 0.8 | \ |
| 21 | 49.1 | 45.8 | 2.6 | 1.6 | 0.8 | \ |
| 22 | 94.3 | 5 | | \ | 0.7 | \ |
| 23 | 48.1 | 36 | 13.6 | 1.8 | 0.5 | \ |
| 24 | 38.6 | 34.2 | 26.8 | 0.4 | \ | \ |
| 25 | 66.8 | 28.3 | 2.3 | 1.6 | \ | \ |

### Example 3—Emissivity and Surface Analysis

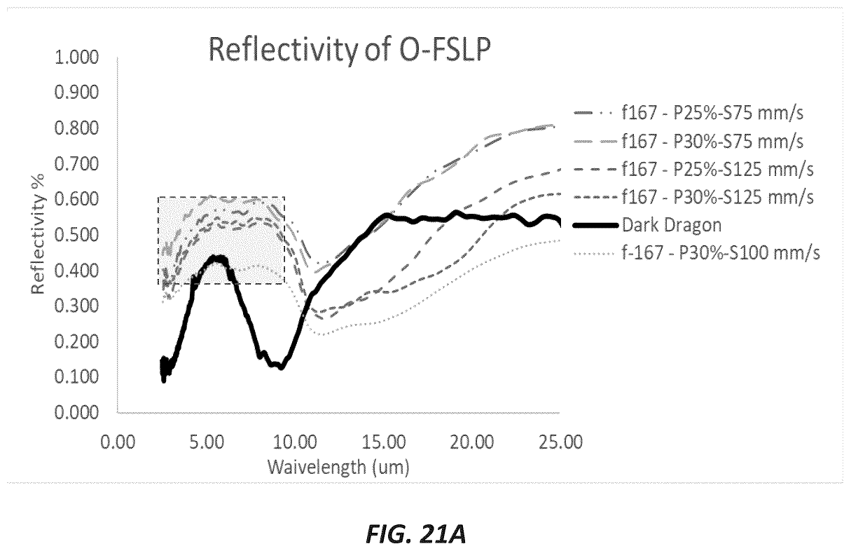

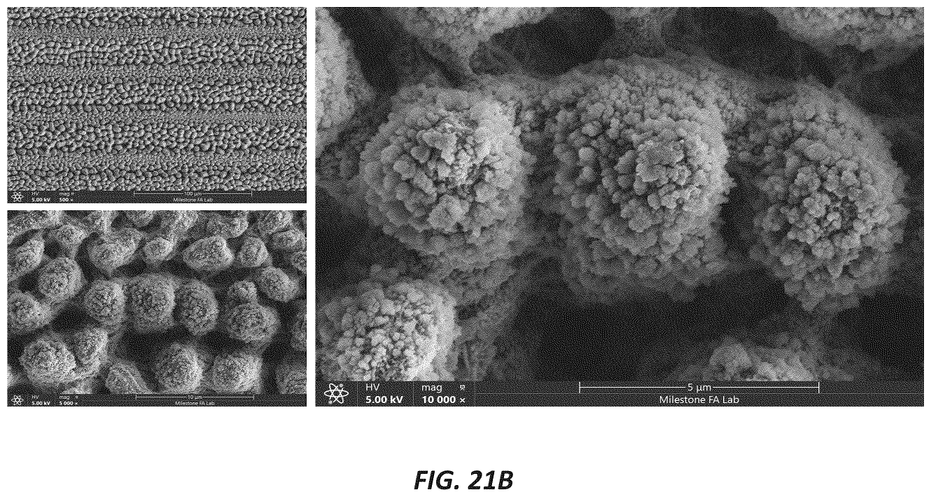

FIG. 21A illustrates the spectral reflectivity versus wavelength of the samples according to some embodiments with F167 optics. The reflectivity is measured at a wavelength in a range of 2 micrometers to 25 micrometers. The F167 optics can generate a laser beam with a spot size or a diameter of about 50 micrometers. The inventors have discovered that a spot size of a scanning laser beam can be an important consideration in defining scanning parameters, such as the distance between two consecutive line scans. As described herein, for a gaussian laser beam, a spot size can refer to a sum of radial distances in opposite directions from the center of the beam to points at which the intensity of the laser beam drops off to about 1/e of a peak intensity at the center. For a spot size of about 50 micrometers, the inventors have discovered that the distance between two consecutive line scanning is about 20 micrometers. The maximum pulse energy is about 100 μJ. Table 6 lists the processing condition for samples shown in FIG. 21A. Each laser pulse is about 20 ps. The samples were processed in the ambient air without a shielding gas. As illustrated in FIG. 21A, the reflectivity of sample Dark Dragon is the target reflectivity. The reflectivity values within the dash box in FIG. 21A are the target reflectivity values in a range of about 0.35 to about 0.6 at a wavelength in a range of about 2 micrometers to about 10 micrometers, such that the target emissivity values have a range of about 0.4 to about 0.65 at a wavelength in a range of about 2 micrometers to about 10 micrometers. The reflectivity of the laser-processed substrate samples listed in Table 6 are within the target reflectivity range. As illustrated in FIG. 21A, the samples processed with scanning speed of about 75 mm/s to 125 mm/s and laser power of 25%-30% are confirmed to have a reflectivity in the target range. In addition, the reflectivity decreases with the increase in scan speed from 75 to 125 mm/s.

TABLE 6

| | Laser scanning | Laser power |
|---|---|---|
| Sample No. | speed (mm/s) | (% of 20 W) |
| F167-P25%-S75 | 75 | 25% |
| mm/s | | |
| F167-P30%-S75 | 75 | 30% |
| mm/s | | |
| F167-P25%-S125 | 125 | 25% |
| mm/s | | |
| F167-P30%-S125 | 125 | 30% |
| mm/s | | |
| F167-P30%-S100 | 100 | 30% |
| mm/s | | |

FIG. 21B shows the SEM images of the surface of the sample F167-P30%-S100 mm/s with different magnifications. As illustrated in FIG. 21C, the laser-processed substrate comprises uniformly distributed microstructures across the sample. The laser-processed substrate comprises a layer of microstructures in the shape of dome. The size of the majority of the microstructures is less than 5 micrometers. The surface of the microstructure is covered by a layer of nanostructures. Table 7 below illustrates the roughness of sample F167-P30%-S100 mm/s measured in various ways.

TABLE 7

| | Rp | Rv | Rz | Ra | Rq | | |
|---|---|---|---|---|---|---|---|
| | [μm] | [μm] | [μm] | [μm] | [μm] | Rsk | Rku |
| F167-5 | 2.716 | 3.362 | 6.077 | 0.991 | 1.214 | −0.124 | 2.503 |

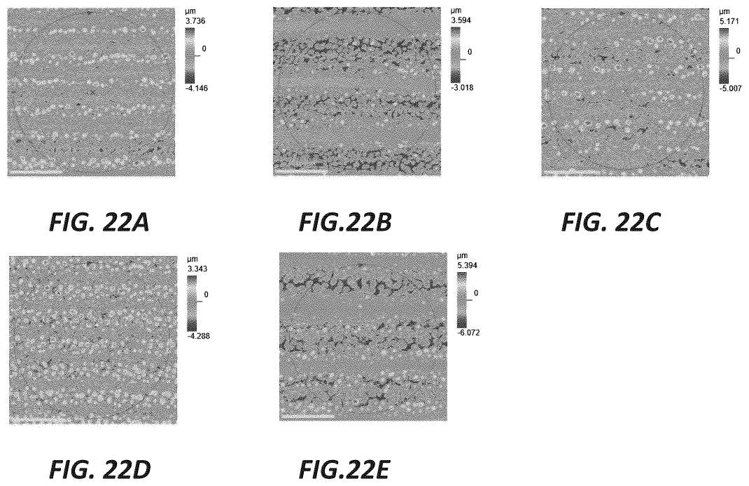

FIGS. 22A-22E illustrate the surface morphology of laser-processed samples with different processing conditions. Table 8-1 and Table 8-2 list the processing conditions, emissivity values, roughness for each sample. Rₐ is the arithmetic average of the absolute values of the profile height deviations from the mean line, recorded within the evaluation length. Rq or Rms refers to quadratic mean, or root mean square average of profile height deviations from the mean line. Rₛₖ refers to skewness, or measure of asymmetry of the profile about the mean line.

As illustrated in Table 8-1 and Table 8-2, the laser power is more effective on Rₐ. The higher the laser power, the higher the Rₐ. In addition, at a constant power, the emissivity first increases with the increase of the scanning speed and then decreases with the increase of the scanning speed after reaching the optimum point. Moreover, the value of Rₛₖ is correlated with emissivity: a higher Rₛₖ indicates a lower emissivity and a higher reflectivity.

TABLE 8-1

| | Laser | Laser | | | | | | | | |
|---|---|---|---|---|---|---|---|---|---|---|
| | scanning | power | | | | | | | | |
| Surface | speed | (% of | | Rp | Rv | Rz | Rc | Rt | Ra | Rq |
| morphology | (mm/s) | 20 W) | Emissivity | [μm] | [μm] | [μm] | [μm] | [μm] | [μm] | [μm] |
| FIG. 22A | 75 | 25% | 0.38 | 2.87 | 3.60 | 6.47 | 2.22 | 6.47 | 0.81 | 1.02 |
| FIG. 22B | 125 | 25% | 0.49 | 2.05 | 2.56 | 4.61 | 2.23 | 4.61 | 0.74 | 0.93 |
| FIG. 22C | 75 | 30% | 0.36 | 3.95 | 4.55 | 8.50 | 3.34 | 8.50 | 1.21 | 1.51 |
| FIG. 22D | 100 | 30% | 0.60 | 2.68 | 3.39 | 6.07 | 2.84 | 6.07 | 1.02 | 1.24 |
| FIG. 22E | 125 | 30% | 0.52 | 3.95 | 4.88 | 8.83 | 3.50 | 8.83 | 1.26 | 1.58 |

TABLE 8-2

| | Laser | Laser | | | | | | | | |
|---|---|---|---|---|---|---|---|---|---|---|
| | scanning | power | | | | | | | | |
| Surface | speed | (% of | | | | Rsm | RΔq | Rδc | Rmr | Rzjis |
| morphology | (mm/s) | 20 W) | Emissivity | Rsk | Rku | [μm] | [°] | [μm] | [%] | [μm] |
| FIG. 22A | 75 | 25% | 0.38 | 0.05 | 3.02 | 6.25 | 61.08 | 1.71 | 15.03 | 5.48 |
| FIG. 22B | 125 | 25% | 0.49 | −0.33 | 2.66 | 5.88 | 60.46 | 1.64 | 48.61 | 4.47 |
| FIG. 22C | 75 | 30% | 0.36 | 0.13 | 2.76 | 7.39 | 66.85 | 2.47 | 11 | 7.52 |
| FIG. 22D | 100 | 30% | 0.60 | −0.10 | 2.43 | 5.49 | 68.06 | 2.34 | 28.65 | 5.70 |
| FIG. 22E | 125 | 30% | 0.52 | −0.57 | 3.04 | 6.85 | 68.85 | 2.80 | 8.37 | 7.57 |

Table 9 lists the processing condition for samples according to some embodiments. Each laser pulse is about 20 ps. The maximum pulse energy is about 100 μJ. The samples were processed with F250 optics for generating the laser. The F250 optics is capable of generating a laser beam having a diameter of 80 micrometers. The distance between two consecutive line scanning is about 50 micrometers. The maximum laser power is 20 W. The maximum pulsed energy is 100 μJ. The samples are processed in the ambient air without a shielding gas.

TABLE 9

| | Laser scanning | Laser power | |
|---|---|---|---|
| Sample No. | speed (mm/s) | (% of 20 W) | Emissivity |
| F250-P60%-S125 | 125 | 60% | / |
| mm/s | | | |
| F250-P65%-S125 | 125 | 65% | / |
| mm/s | | | |
| F250-P70%-S125 | 125 | 70% | / |
| mm/s | | | |
| F250-P75%-S125 | 125 | 75% | 0.33 |
| mm/s | | | |
| F250-P60%-S150 | 150 | 60% | / |
| mm/s | | | |
| F250-P65%-S150 | 150 | 65% | / |
| mm/s | | | |
| F250-P70%-S150 | 150 | 70% | / |
| mm/s | | | |
| F250-P75%-S150 | 150 | 75% | / |
| mm/s | | | |
| F250-P60%-S200 | 200 | 60% | / |
| mm/s | | | |
| F250-P65%-S200 | 200 | 65% | / |
| mm/s | | | |
| F250-P70%-S200 | 200 | 70% | / |
| mm/s | | | |
| F250-P75%-S200 | 200 | 75% | / |
| mm/s | | | |
| F250-P60%-S250 | 250 | 60% | 0.39 |
| mm/s | | | |
| F250-P65%-S250 | 250 | 65% | / |
| mm/s | | | |
| F250-P70%-S250 | 250 | 70% | / |
| mm/s | | | |
| F250-P75%-S250 | 250 | 75% | 0.25 |
| mm/s | | | |

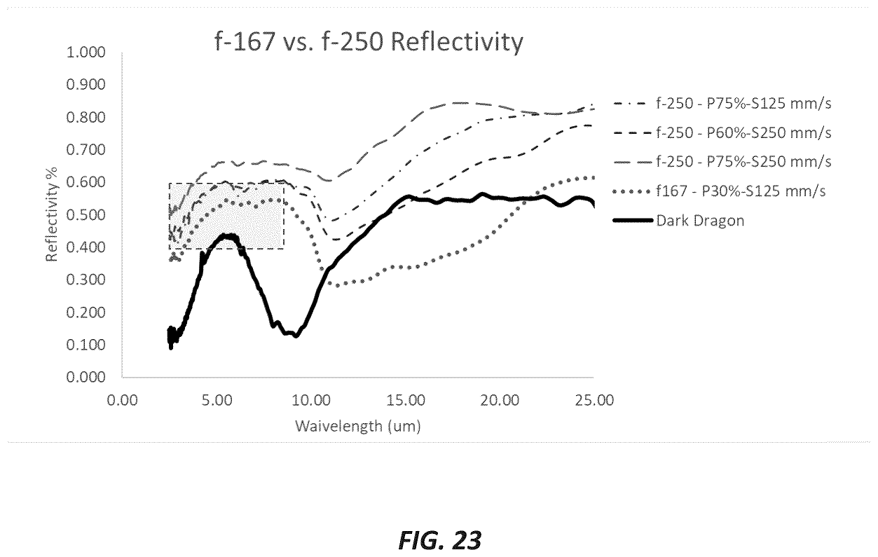

FIG. 23 illustrates the spectral reflectivity versus wavelength of some of the samples listed in Table 9. The reflectivity of sample Dark Dragon is the target reflectivity. The dash box is the range for the target reflectivity range. The reflectivity is measured at a wavelength range of 2 micrometers to 25 micrometers. As illustrated in FIG. 23, the range of the reflectivity of the laser-processed substrate samples listed in Table 9 with F250 optics are higher than that of the samples processed with F167 optics.

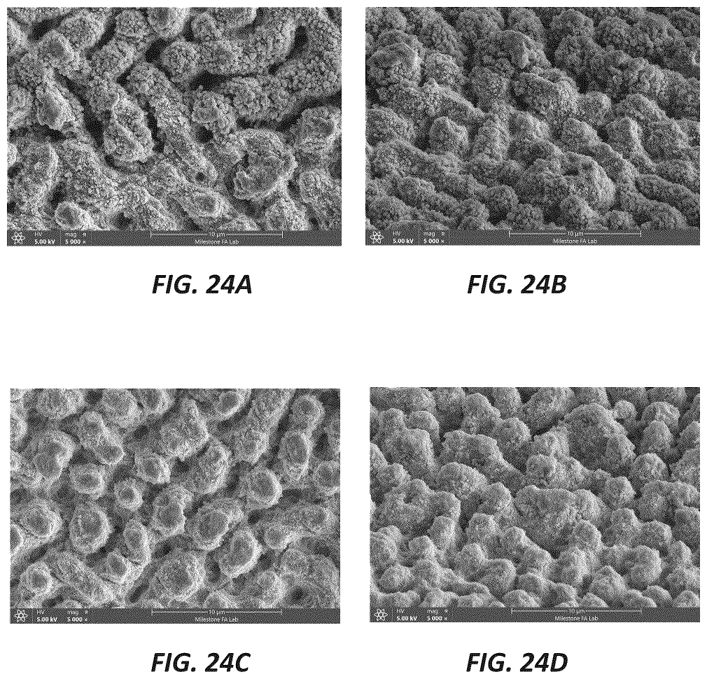

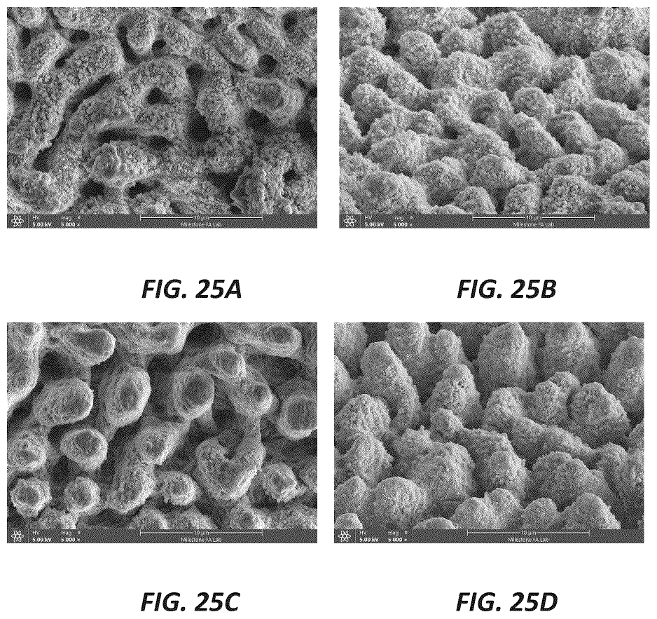

FIGS. 24A-24B show the SEM images of surface of sample F250-P60%-S125 mm/s with different angles. FIGS. 24C-24D show the SEM images of surface of sample F250-P60%-S250 mm/s with different angles. FIGS. 25A-25B show the SEM images of surface of sample F250-P75%-S125 mm/s with different angles. FIGS. 25C-25D show the SEM images of surface of sample F250-P75%-S250 mm/s with different angles. Comparing the SEM images in FIGS. 24A-25D, the formed microstructures with different scanning speed and same laser power are similar. Thus, the effect of scanning speed of the laser on texturing is insignificant. In addition, the surface of the microstructures is coarser when the power of the laser increases from 60% to 75% with the same laser scanning speed.

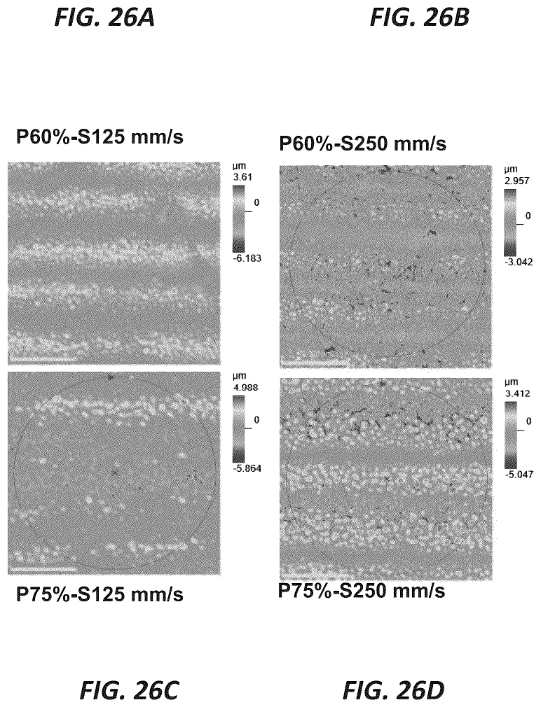

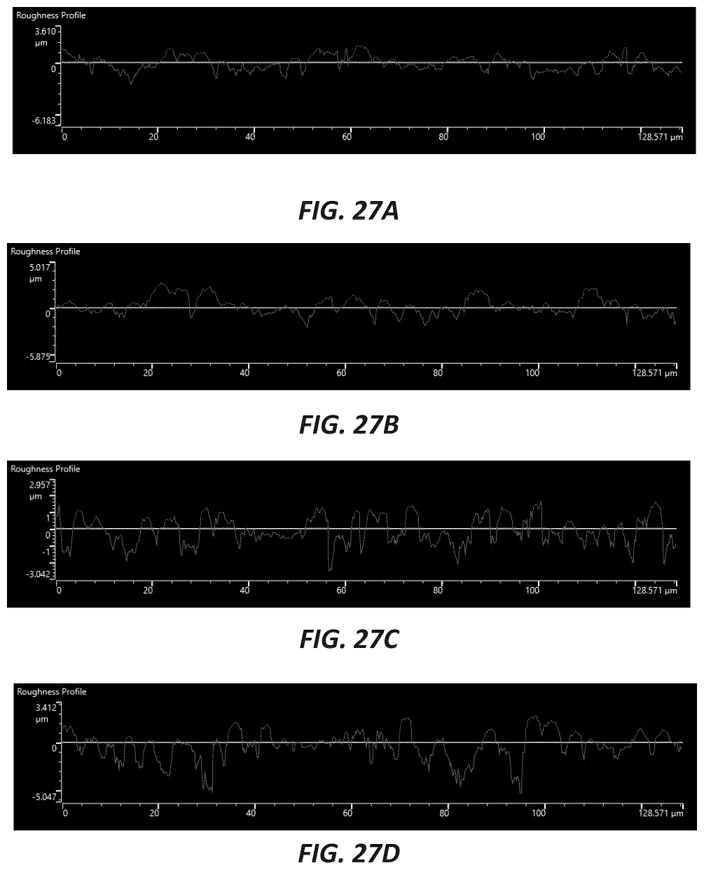

FIGS. 26A-26D illustrate the surface morphology of samples F250-P60%-S125 mm/s, F250-P60%-S250 mm/s, F250-P75%-S125 mm/s, and F250-P75%-S250 mm/s respectively. Table 10 summarizes the processing conditions, emissivity values, roughness for each sample. FIGS. 27A-27D illustrate the roughness profile in the Y direction (perpendicular to the laser scanning direction) of samples F250-P60%-S125 mm/s, F250-P60%-S250 mm/s, F250-P75%-S125 mm/s, and F250-P75%-S250 mm/s respectively.

TABLE 10

| | Surface | Laser scanning | Laser power | Emis- | Ra |
|---|---|---|---|---|---|
| Sample No. | morphology | speed (mm/s) | (% of 20 W) | sivity | [μm] |
| F250-P60%- | FIG. 27A | 125 | 60% | \ | 0.715 |
| S125 mm/s | | | | | |
| F250-P60%- | FIG. 27B | 250 | 60% | 0.39 | 0.624 |
| S250 mm/s | | | | | |
| F250-P75%- | FIG. 27C | 125 | 75% | 0.33 | 0.84 |
| S125 mm/s | | | | | |
| F250-P75%- | FIG. 27D | 250 | 75% | 0.25 | 0.9 |
| S250 mm/s | | | | | |

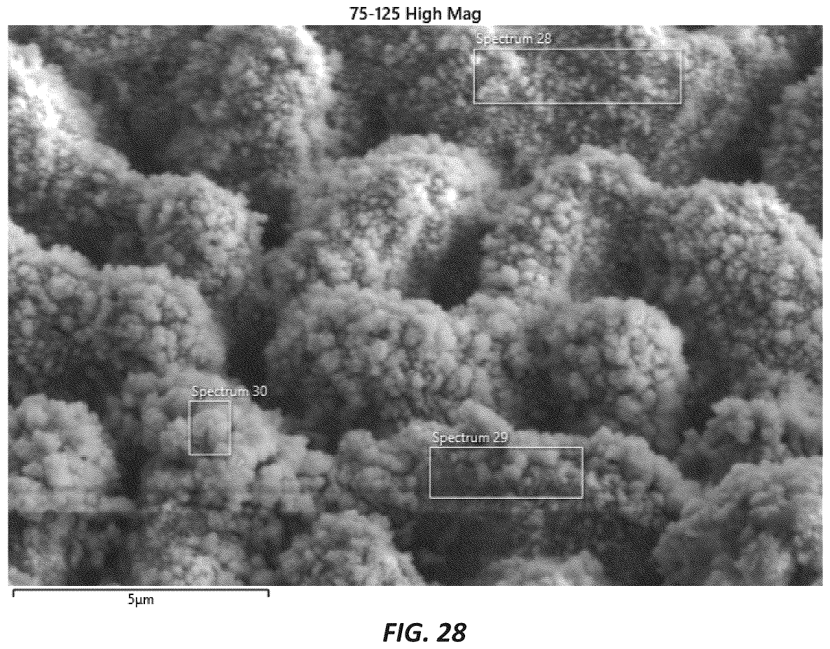

FIG. 28 shows the SEM image of the surface of sample F250-P75%-S125 mm/s. Table 11 summarizes the percentage of elements at each spot as illustrated in FIG. 28 based on the EDS analysis. As shown in Table 11, the surface nanostructures comprise essentially of Al and O. Thus, this confirms that the surface nanostructures comprise aluminum oxide. The existence of nitrogen and carbon suggests air entrapment during laser processing.

TABLE 11

| Spectrum | Al | O | C | N | Mg | Si |
|---|---|---|---|---|---|---|
| No. | (at %) | (at %) | (at %) | (at %) | (at %) | (at %) |
| 28 | 61.4 | 30.1 | 4.1 | 1.6 | 2.4 | 0.5 |
| 29 | 61.8 | 33.8 | 2.4 | 1.2 | 0.8 | \ |
| 30 | 38.7 | 54.7 | 4.7 | 1.3 | 0.7 | \ |

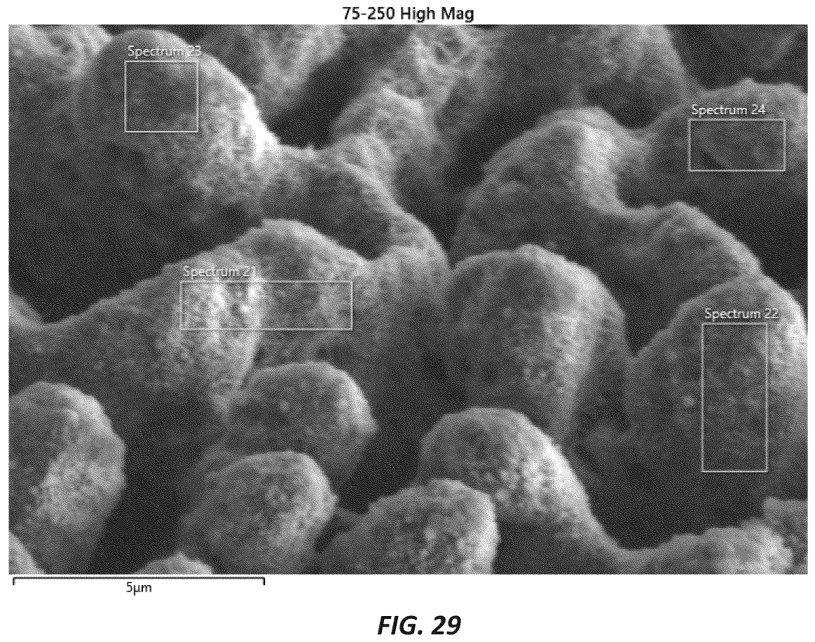

FIG. 29 shows the SEM image of the surface of sample F250-P75%-250 mm/s. Table 12 summarizes the percentage of elements at each spot as illustrated in FIG. 29 based on the EDS analysis. As shown in Table 12, the surface nanostructures comprise essentially of Al and O. Thus, this confirms that the surface nanostructures comprise aluminum oxide.

TABLE 12

| Spectrum | Al | O | Si | N | Mg |
|---|---|---|---|---|---|
| No. | (at %) | (at %) | (at %) | (at %) | (at %) |
| 21 | 73.4 | 21.7 | \ | 2.2 | 2.7 |
| 22 | 77.9 | 18.4 | \ | 2.4 | 1.3 |
| 23 | 69.3 | 20.2 | 1.9 | 2.7 | 6.0 |

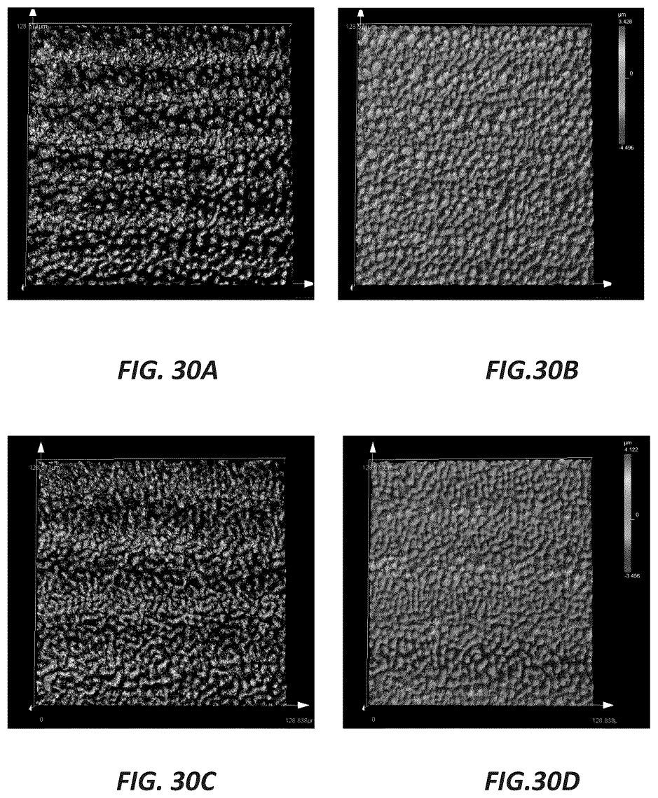

FIGS. 30A-30D compare the surface morphology of the laser-processed samples with normal optics and fast yield optics. FIGS. 30A-30B show the surface morphology of laser-processed sample with normal optics (F-167). FIGS. 30C-30D show the surface morphology of laser-processed sample with fast yield optics (F-250). As illustrated in FIGS. 30A-30D, both optics create similar surfaces morphologies. As illustrated in FIGS. 30C-30D, the samples processed with fast yield optic have slightly smoother surface. The processing speed for high yield samples can be up to 4 times faster than the normal optics. Table 13 summarizes the roughness of the samples measured with different optics.

TABLE 13

| | Rp | Rv | Rz | Rc | Rt | Ra | Rq | | | Rsm | RΔq | Rδc | Rmr | Rzjis |
|---|---|---|---|---|---|---|---|---|---|---|---|---|---|---|
| | [μm] | [μm] | [μm] | [μm] | [μm] | [μm] | [μm] | Rsk | Rku | [μm] | [°] | [μm] | [%] | [μm] |
| Normal | 2.72 | 3.36 | 6.08 | 2.81 | 6.08 | 0.99 | 1.21 | −0.12 | 2.50 | 5.57 | 67.28 | 2.22 | 32.36 | 5.61 |
| Optics | | | | | | | | | | | | | | |
| (F167) | | | | | | | | | | | | | | |
| Fast | 3.41 | 2.72 | 6.13 | 2.07 | 6.13 | 0.75 | 0.97 | 0.19 | 3.47 | 6.42 | 60.05 | 1.46 | 7.26 | 5.3 |
| Yield | | | | | | | | | | | | | | |
| Optics | | | | | | | | | | | | | | |
| (F250) | | | | | | | | | | | | | | |

### Example 4—Protective Top Coating and Cleaning Processing

After the substrate samples were laser-processed, a layer of aluminum oxide (AlO) or YAG was deposited on the laser-processed substrate sample with different thickness as a protective top-coating layer. The protective top-coating layer was deposited by atomic layer deposition (ALD) process. Table 14 summarizes the parameters of the AlO protective layer. After the deposition of protective top-coating layer, the samples were cleaned with ClF₃ gas cleaning process.

TABLE 14

| Coating | Thickness (nm) | Size |
|---|---|---|
| AlO | 250 | 1 × 1 |
| AlO | 500 | 1 × 1, 2 × 2 |
| AlO | 1000 | 1 × 1 |
| AlO | 1500 | 1 × 1 |
| YAG | 500 | 1 × 1 & 2 × 2 |

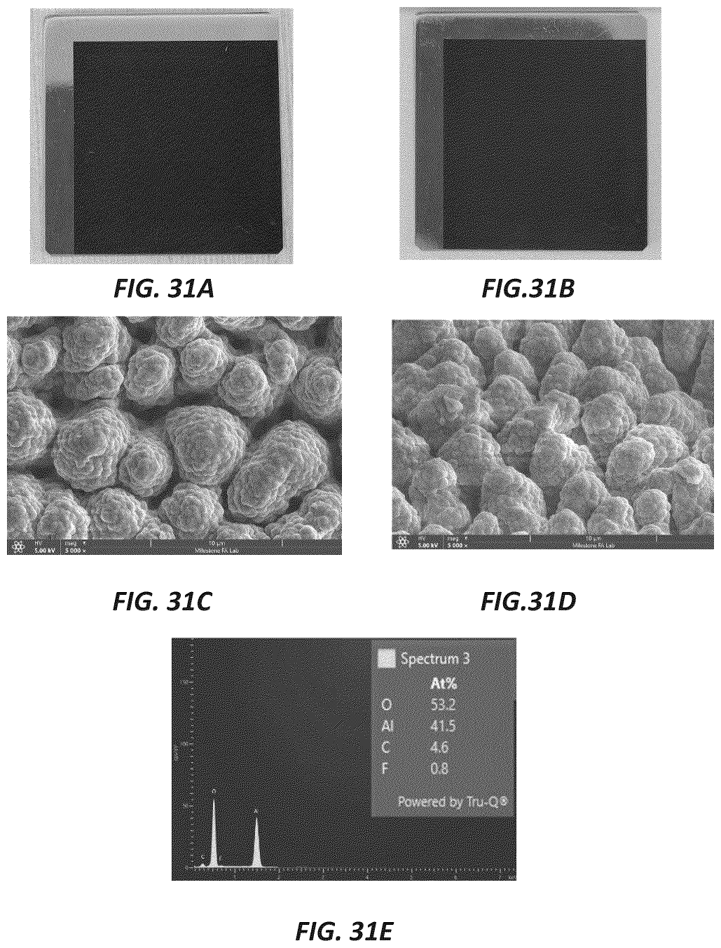

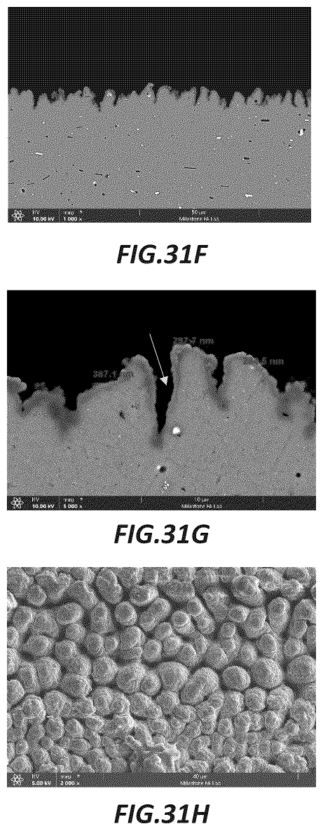

FIG. 31A shows an image of a laser-processed substrate sample covered with a dense aluminum oxide (AlO) layer having a thickness of about 250 nm. The AlO layer was deposited with atomic layer deposition (ALD). FIG. 31B shows an image of the sample in FIG. 31A after being cleaned with ClF₃. As illustrated in FIG. 31B, no pits or cracks can be visually identified on the sample surface. FIG. 31C illustrates a top view SEM image of the surface of the sample in FIG. 31B after the ClF₃ processing. FIG. 31D illustrates a titled SEM image of the surface of the sample in FIG. 31B after the ClF3 processing. As illustrated in FIGS. 31C and 31D, the microstructures stay unaffected by the ClF₃ cleaning. There are no thermal cracks identified on the dense AlO layer. FIG. 31E illustrates the EDS analysis of the surface in FIG. 31D after the cleaning process. As illustrated in FIG. 31E, the surface comprises essentially of aluminum oxide. FIGS. 31F and 31G illustrate the cross-section view of the sample in FIG. 31B after ClF₃ cleaning with different magnifications. As illustrated in FIGS. 31F and 31G, the measured thickness of the dense AlO layer is about 387 nm, 298 nm, 285 nm at different locations. The cross section view confirms that there is no thermal cracking or corrosion spots. The valleys of the microstructures created during the laser processing are hardly filled by the dense AlO layer. FIG. 31H illustrates a top down view of the sample in FIG. 31B after the ClF₃ cleaning process with a ×2000 magnification.

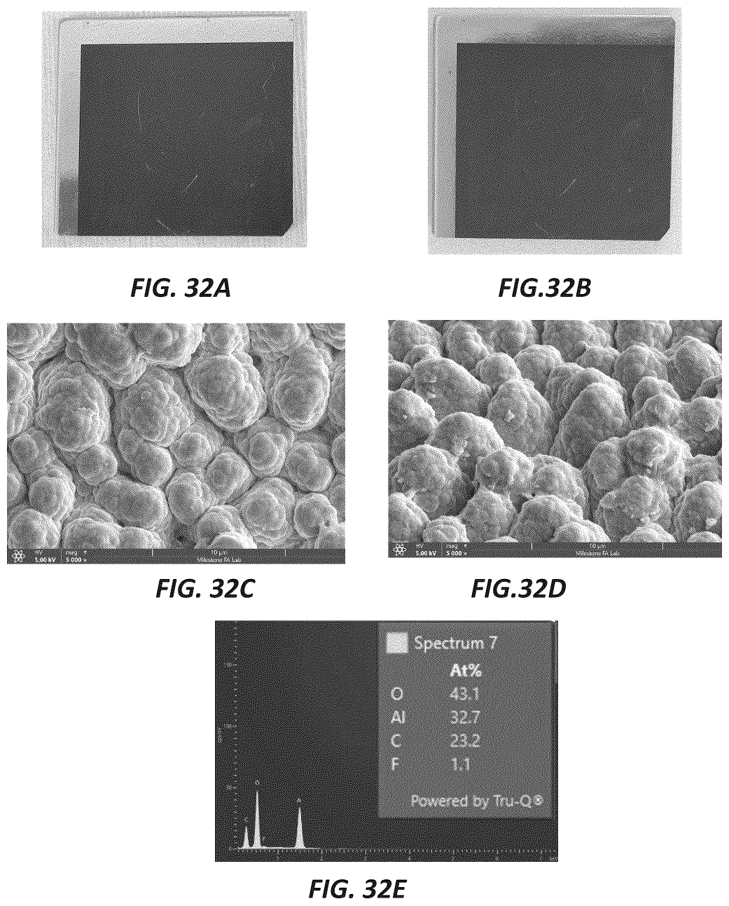

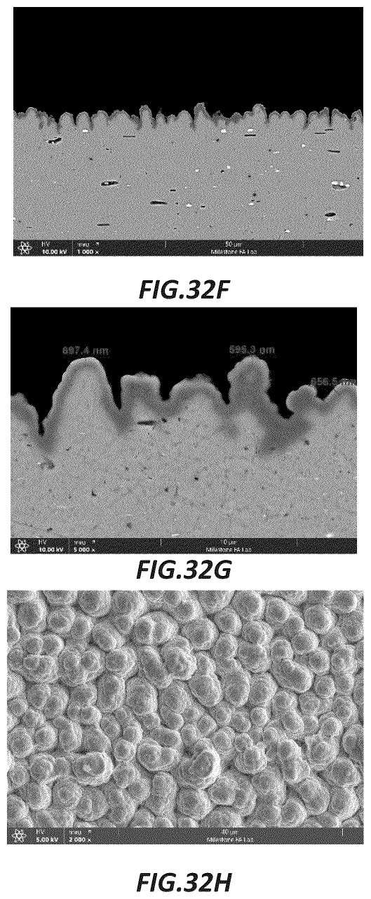

FIG. 32A shows an image of a laser-processed substrate sample covered with a dense AlO layer having a thickness of about 500 nm. The AlO layer was deposited with atomic layer deposition (ALD). FIG. 32B shows an image of the sample in FIG. 32A after being cleaned with ClF₃ in the process described above. As illustrated in FIG. 32B, no additional pits or cracks can be visually identified on the sample surface after the ClF₃ cleaning process. FIG. 32C illustrates a top view SEM image of the surface of the sample in FIG. 32B after the ClF₃ processing. FIG. 32D illustrates a titled SEM image of the surface of the sample in FIG. 32B after the ClF₃ processing. As illustrated in FIGS. 32C and 32D, the microstructures stay unaffected by the ClF₃ cleaning. There are no thermal cracks identified on the dense AlO layer. FIG. 32E illustrates the EDS analysis of the surface in FIG. 32D after the cleaning process. As illustrated in FIG. 32E, the surface comprises essentially of aluminum oxide. FIGS. 32F and 32G illustrate the cross-section view of the sample in FIG. 32B after ClF₃ cleaning with different magnifications. As illustrated in FIGS. 32F and 32G, the measured thickness of the dense AlO layer is about 697 nm, 595 nm, 656 nm at different locations. FIG. 32H illustrates a top down view of the sample in FIG. 32B after the ClF₃ cleaning process with a ×2000 magnification. As illustrated in FIGS. 32F-32H, there is no thermal cracking or corrosion spot identified. The valleys of the microstructures created during the laser processing are moderately filled by the dense AlO layer.

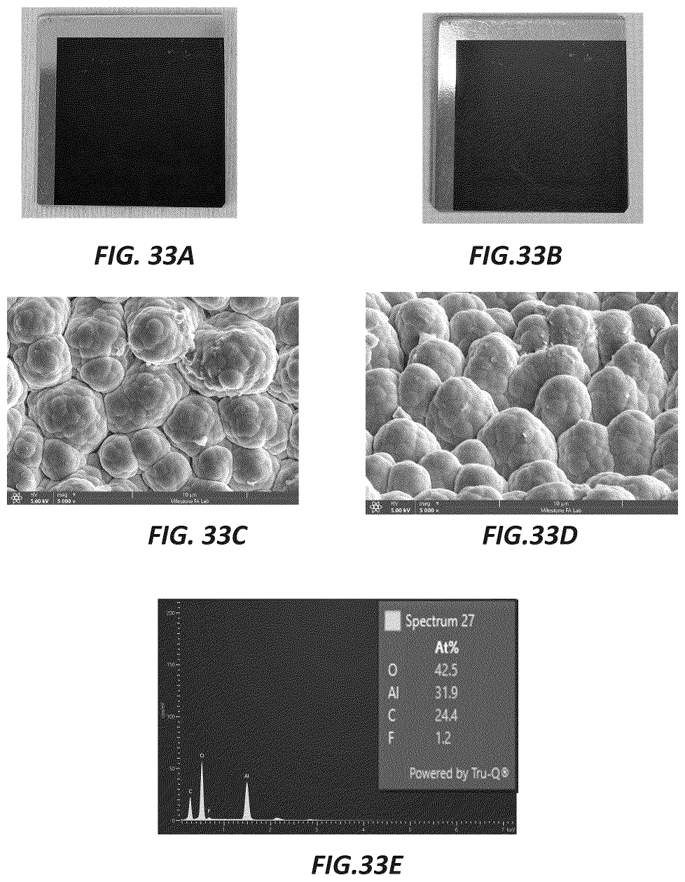

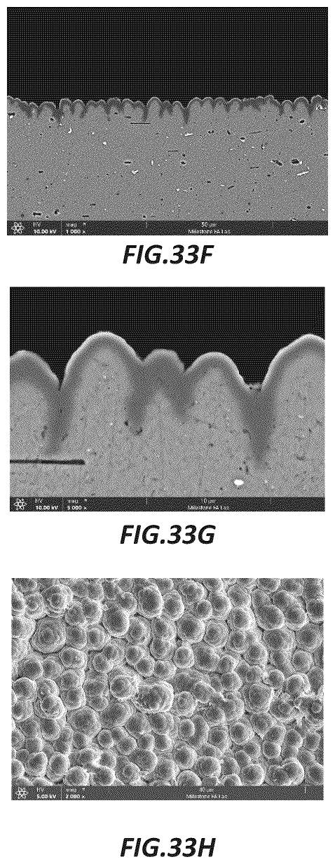

FIG. 33A shows an image of a laser-processed substrate sample covered with a dense AlO layer having a thickness of about 1000 nm. The AlO layer was deposited with atomic layer deposition (ALD). FIG. 33B shows an image of the sample in FIG. 33A after being cleaned with ClF₃ in the process described above. As illustrated in FIG. 33B, no additional pits or cracks can be visually identified on the sample surface after the ClF₃ cleaning process. FIG. 33C illustrates a top view SEM image of the surface of the sample in FIG. 33B after the ClF₃ processing. FIG. 33D illustrates a titled SEM image of the surface of the sample in FIG. 33B after the ClF₃ processing. As illustrated in FIGS. 33C and 33D, the microstructures stay unaffected by the ClF₃ cleaning. The valleys of the microstructures are at least partially filled with the dense AlO layer. There are no thermal cracks identified on the dense AlO layer. FIG. 33E illustrates the EDS analysis of the surface in FIG. 33D after the cleaning process. As illustrated in FIG. 33E, the surface comprises essentially of aluminum oxide. FIGS. 33F and 33G illustrate the cross-section view of the sample in FIG. 33B after ClF3 cleaning with different magnifications. FIG. 33H illustrates a top-down view of the sample in FIG. 33B after the ClF₃ cleaning process with a ×2000 magnification. As illustrated in FIGS. 33F-33H, there is no thermal cracking or corrosion spot identified. The valleys of the microstructures created during the laser processing are mostly filled by the dense AlO layer.

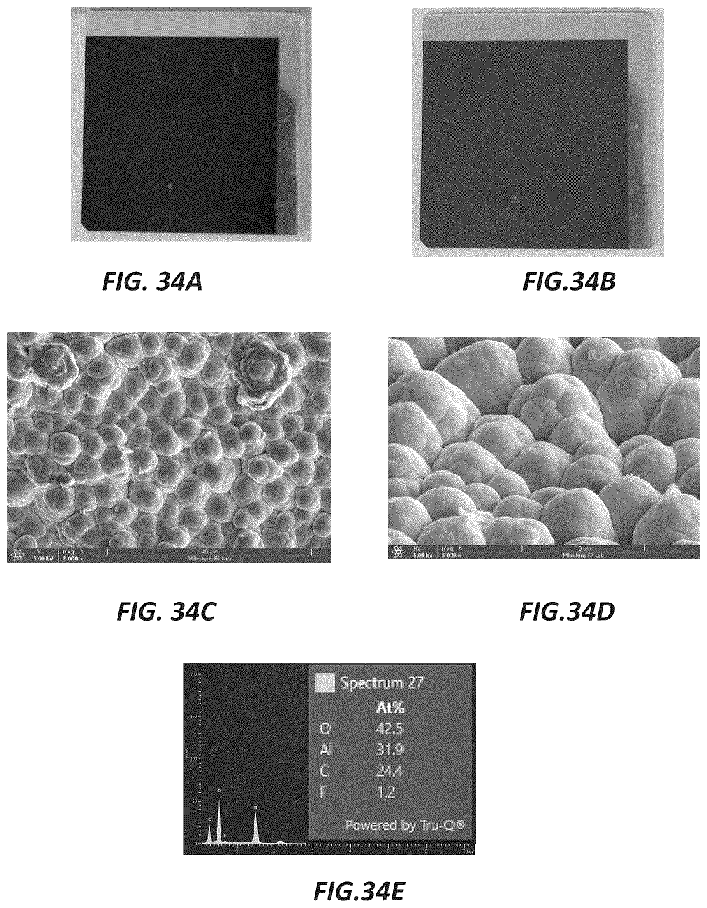

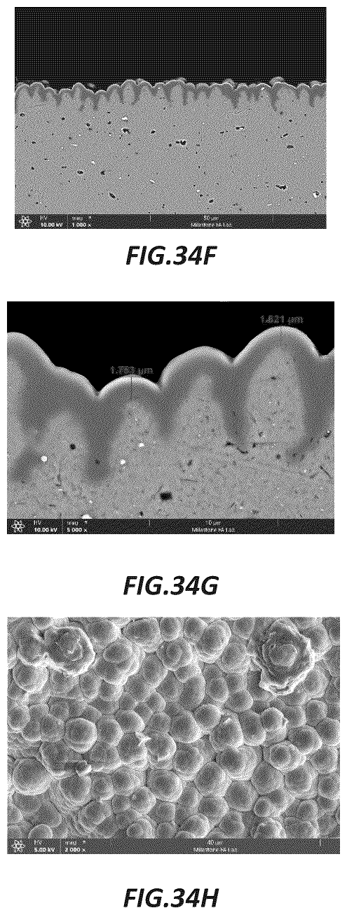

FIG. 34A shows an image of a laser-processed substrate sample covered with a dense AlO layer having a thickness of about 1500 nm. The AlO layer was deposited with atomic layer deposition (ALD). FIG. 34B shows an image of the sample in FIG. 34A after being cleaned with ClF₃ in the process described above. As illustrated in FIG. 34B, no additional pits or cracks can be visually identified on the sample surface after the ClF₃ cleaning process. FIG. 34C illustrates a top view SEM image of the surface of the sample in FIG. 34B after the ClF₃ processing. FIG. 34D illustrates a titled SEM image of the surface of the sample in FIG. 34B after the ClF₃ processing. As illustrated in FIGS. 34C and 34D, the microstructures stay unaffected by the ClF₃ cleaning. The valleys of the microstructures are mostly filled with the dense AlO layer. There are no thermal cracks identified on the dense AlO layer. FIG. 34E illustrates the EDS analysis of the surface in FIG. 34D after the cleaning process. As illustrated in FIG. 34E, the surface comprises essentially of aluminum oxide. FIGS. 34F and 34G illustrate the cross-section view of the sample in FIG. 34B after ClF₃ cleaning with different magnifications. As illustrated in FIGS. 34F and 34G, the thickness of the dense AlO layer is reduced to about 1753 nm and 1621 nm at different locations. FIG. 34H illustrates a top down view of the sample in FIG. 34B after the ClF₃ cleaning process with a ×2000 magnification. As illustrated in FIGS. 34F-34H, there is no thermal cracking or corrosion spot identified. The valleys of the microstructures created during the laser processing are completely filled by the dense AlO layer. As the valleys are completely filled by the dense AlO layer, the chance of particle generation when the substrate is used in a cyclic deposition is greatly reduced because the AlO layer eliminates the dead volume.

As illustrated in FIGS. 31B, 32B, 33B and 34B, there are no visually identified pits or cracks formed after the ClF₃ cleaning. As illustrated in FIGS. 31D, 32D, 33D and 34D, as the dense AlO layer becomes thicker, the valleys of the microstructures formed after the laser processing are filled with the dense AlO layer. There are no obvious signs of thermal cracking of the dense AlO layer during or after the ClF₃ cleaning process. The EDS analysis shows that there is high percentage of O from the AlO layer remains on the surface after the ClF₃ cleaning.

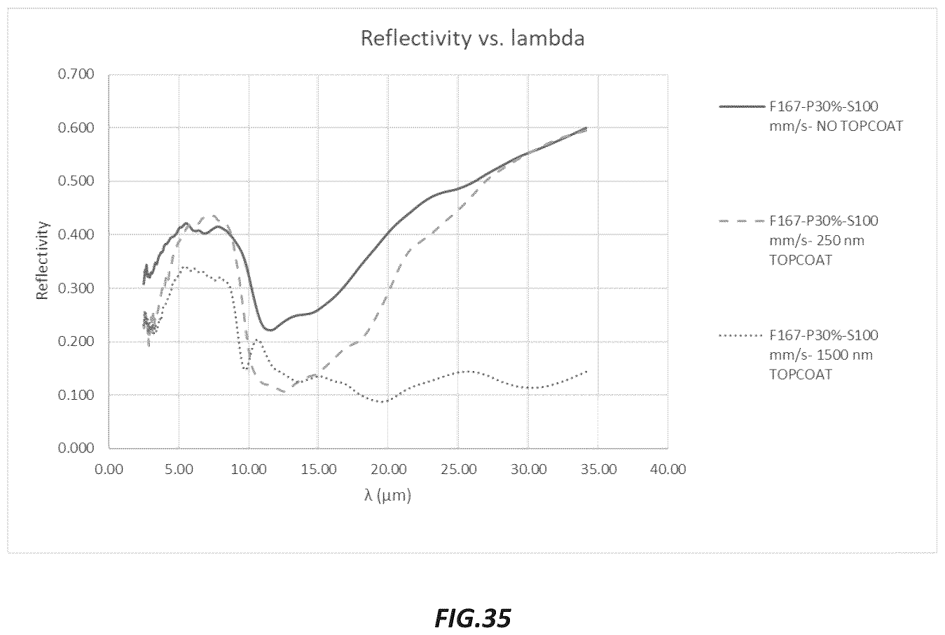

FIG. 35 shows the spectral reflectivity versus wavelength of the samples covered with protective top-coatings having different thickness according to some embodiments. As illustrated in FIG. 35, the formation of a protective top-coating on the laser-textured surface does not substantially change the reflectivity of a laser-textured surface without a protective top-coating. In addition, the formation of a protective top-coating with a thickness of 1500 nm on the laser-textured surface is decreased comparing to a laser-textured surface without a protective top-coating.

### E. EXAMPLE EMBODIMENTS

The following example embodiments identify some possible permutations of combinations of features disclosed herein, although other permutations of combinations of features are also possible.
1. A gas diffuser plate configured to diffuse gases delivered into a cyclic deposition chamber, the gas diffuser plate as fabricated comprising:
   a gas diffuser plate having a laser-textured surface configured to face a substrate when present in the cyclic deposition chamber,
   wherein the laser-textured surface comprises microstructures to provide an emissivity of the gas diffuser plate between about 0.4 and about 0.9.
2. The gas diffuser plate of Embodiment 1, wherein the laser-textured surface comprises stripes of laser scanning marks extending in a direction parallel to a laser scanning direction characteristic of laser texturing.
3. The gas diffuser plate of Embodiment 2, wherein the stripes correspond to regions where laser scanning lines overlap.
4. The gas diffuser plate of Embodiment 2 or Embodiment 3, wherein the laser scanning marks comprise microstructures having substantially different sizes or textures relative to sizes or textures of microstructures in regions of the laser-textured surface between adjacent laser scanning marks where laser scanning lines do not overlap.
5. The gas diffuser plate of any one of Embodiments 1-4, further comprising a corrosion-resistant material coating the laser-textured surface.
6. The gas diffuser plate of Embodiment 5, wherein the corrosion-resistant material substantially does not change the emissivity of the gas diffuser plate such that the gas diffuser plate having the corrosion-resistant material coated thereon has an emissivity between about 0.4 and about 0.9.
7. The gas diffuser plate of any one of Embodiments 1-6, wherein the emissivity of the gas diffuser plate is between about 0.4 and about 0.65.
8. The gas diffuser plate of any one of Embodiments 1-7, wherein the laser-textured surface is configured to modulate the emissivity of the gas diffuser plate to match an emissivity of a deposited material on the substrate.
9. The gas diffuser plate of any one of Embodiments 1-8, wherein the microstructures have a general shape of a dome or a pillar.
10. The gas diffuser plate of any one of Embodiments 1-9, wherein the microstructures have an average peak-to-valley height of about 1 micrometer to 10 micrometers.
11. The gas diffuser plate of any one of Embodiments 1-10, wherein the microstructures have an average peak-to-valley height of about 2 micrometers to 5 micrometers.
12. The gas diffuser plate of any one of Embodiments 1-11, wherein the microstructures have an average width measured at bases thereof of about 1 micrometer to 10 micrometers.
13. The gas diffuser plate of any one of Embodiments 1-12, wherein each microstructure comprises a metal core integrally protruding from a bulk substrate portion of the gas diffuser plate, and further comprises a layer of oxide formed on the metal core.
14. The gas diffuser plate of any one of Embodiments 1-13, wherein each microstructure has formed on a surface thereof a plurality of nanostructures, wherein the nanostructures have a maximum dimension that is smaller than a maximum dimension of the microstructures by at least two orders of magnitude.
15. The gas diffuser plate of Embodiment 14, wherein the nanostructures comprise an average size of less than 10 nm.
16. The gas diffuser plate of any one of Embodiments 1-15, wherein the corrosion-resistant material is configured to reduce particle contamination generated from corrosion of the gas diffuser plate by a fluorine-containing cleaning gas.
17. The gas diffuser plate of any one of Embodiments 1-16, wherein the corrosion-resistant material is resistant to the corrosion of a fluorine-containing cleaning gas when present in the cyclic deposition chamber.
18. The gas diffuser plate of Embodiment 17, wherein the fluorine-containing cleaning gas comprises NF₃, F₂, Ar, ClF₃, or combinations thereof.
19. The gas diffuser plate of any one of Embodiments 1-18, wherein the corrosion-resistant material comprises aluminum oxide.
20. The gas diffuser plate of any one of Embodiments 1-19, wherein the corrosion-resistant material is transparent or translucent.
21. The gas diffuser plate of any one of Embodiments 1-20, wherein the corrosion-resistant material is deposited by a method comprising atomic layer deposition (ALD).
22. The gas diffuser plate of any one of Embodiments 1-21, wherein the laser-textured surface reduces an amount of radiation emission from the substrate being reflected by the gas diffuser plate.
23. The gas diffuser plate of any one of Embodiments 1-22, wherein the laser-textured surface comprises a plurality of regions, and wherein each region has an emissivity value different from those of neighboring regions by at least 10%.
24. The gas diffuser plate of Embodiment 23, wherein the plurality of regions is arranged as concentrically defined rings.
25. A gas diffuser plate for diffusing gases delivered into a cyclic deposition chamber configured to deposit a material on a wafer, the gas diffuser plate as fabricated comprising:
   a diffuser plate having a laser-textured surface at a side configured to face the wafer when present in the cyclic deposition chamber; and
   a corrosion-resistant coating formed on the laser-textured surface,
   wherein the laser-textured surface comprises microstructures to provide an emissivity of the gas diffuser plate between about 0.2 and about 0.9.
26. The gas diffuser plate of Embodiment 25, wherein the laser-textured surface comprises stripes of laser scanning marks extending in a direction parallel to a laser scanning direction characteristic of laser texturing.
27. The gas diffuser plate of Embodiment 26, wherein the stripes correspond to regions where laser scanning lines overlap.
28. The gas diffuser plate of Embodiment 26 or Embodiment 27, wherein the laser scanning marks comprise microstructures having substantially different sizes or textures relative to sizes or textures of microstructures in regions of the laser-textured surface between adjacent laser scanning marks where laser scanning lines do not overlap.
29. The gas diffuser plate of any one of Embodiments 25-28, wherein the corrosion-resistant coating is configured to reduce particle generation from the corrosion of the laser-textured surface or the diffuser plate.
30. The gas diffuser plate of any one of Embodiments 25-29, wherein the laser-textured surface is configured to modulate the emissivity of the gas diffuser plate to a value between about 0.4 and about 0.65.
31. The gas diffuser plate of any one of Embodiments 25-30, wherein the corrosion-resistant coating is corrosion resistant to a cleaning gas comprising a fluorine-containing gas.
32. The gas diffuser plate of Embodiment 31, wherein the fluorine-containing comprises NF₃, F₂, Ar, ClF₃, or combinations thereof.
33. The gas diffuser plate of any one of Embodiments 25-32, wherein the laser-textured surface reduces an amount of radiation emission from the wafer being reflected by the gas diffuser plate.
34. The gas diffuser plate of any one of Embodiments 25-33, wherein the microstructures comprise a general shape of a dome or a pillar.
35. The gas diffuser plate of any one of Embodiments 25-34, wherein the microstructures comprise an average peak-to-valley height of about 1 micrometer to 10 micrometers.
36. The gas diffuser plate of any one of Embodiments 25-35, wherein the microstructures comprise an average peak-to-valley height of about 2 micrometers to 5 micrometers.
37. The gas diffuser plate of any one of Embodiments 25-36, wherein the microstructures comprise a width measured at bases thereof of about 1 micrometer to 10 micrometers.
38. The gas diffuser plate of any one of Embodiments 25-37, wherein each microstructure comprises a metal core integrally protruding from a bulk substrate portion of the gas diffuser plate, and further comprises a layer of oxide formed on the metal core.
39. The gas diffuser plate of any one of Embodiments 25-38, wherein each microstructure has formed on a surface thereof a plurality of nanostructures, wherein the nanostructures have a maximum dimension that is smaller than a maximum dimension of the microstructures by at least two orders of magnitude.
40. The gas diffuser plate of Embodiment 39, wherein the nanostructures comprise an average size of less than 10 nm.
41. The gas diffuser plate of any one of Embodiments 25-40, wherein the corrosion-resistant coating comprises aluminum oxide.
42. The gas diffuser plate of any one of Embodiments 25-41, wherein the corrosion-resistant coating is deposited by a method comprising atomic layer deposition (ALD).
43. The gas diffuser plate of any one of Embodiments 35-42, wherein the laser-textured surface comprises a plurality of regions, and wherein each region has an emissivity value different from those of neighboring regions by at least 10%.
44. The gas diffuser plate of Embodiment 43, wherein the plurality of regions is arranged as concentrically defined rings.
45. A method of fabricating a diffuser plate for diffusing gases delivered into a cyclic deposition chamber, the method comprising:
   providing a substrate diffuser plate having a substrate emissivity; and
   texturing a surface of the substrate gas diffuser plate with a pulsed laser beam to form a laser-textured surface comprising microstructures, such that the laser-textured surface has an emissivity that is higher than the substrate emissivity and between about 0.2 and about 0.9.
46. The method of Embodiment 45, wherein texturing comprises scanning with the laser beam at a scanning speed of about 60 mm/s to about 200 mm/s.
47. The method of Embodiment 45 or 46, wherein texturing comprises consecutive line scanning the surface of the substrate gas diffuser plate with the pulsed laser beam.
48. The method of any one of Embodiments 45, wherein the pulsed laser beam overlaps with another pulsed laser beam in adjacent line scanning.
49. The method of any one of Embodiments 45, wherein the laser beam has a pulse energy of about 15 μJ to about 40 μJ.
50. The method of any one of Embodiments 45-49, wherein the emissivity is between about 0.2 to about 0.7.
51. The method of any one of Embodiments 45-50, further comprising forming a protective layer on the laser-textured surface.
52. The method of Embodiment 51, wherein forming the protective layer comprises depositing by atomic layer deposition.
53. The method of Embodiment 51 or Embodiment 52, wherein the protective layer is a conformal layer.
54. The method of any one of Embodiments 51-53, wherein the protective layer comprises aluminum oxide.
55. The method of any one of Embodiments 45-54, wherein the laser-textured surface comprises a plurality of regions, wherein each region has an emissivity value different from those of neighboring regions by at least 10%.
56. The gas diffuser plate of Embodiment 55, wherein the plurality of regions is arranged as concentrically defined rings.
57. A diffuser plate having a laser-textured surface for a cyclic deposition process, the laser-textured surface comprising microstructures configured to provide an emissivity of the gas diffuser plate between about 0.2 and about 0.9.
58. The diffuser plate of Embodiment 57, wherein the microstructures comprise an average peak-to-valley height of about 1 to 10 micrometers.
59. The diffuser plate of Embodiment 57 or Embodiment 58, wherein a conformal protective layer formed on the laser-textured surface.
60. The diffuser plate of any one of Embodiments 57-59, wherein the laser-textured surface comprises stripes of laser scanning marks extending in a direction parallel to a laser scanning direction characteristic of laser texturing.
61. The diffuser plate of any one of Embodiments 57-60, wherein the stripes correspond to regions where laser scanning lines overlap.
62. The diffuser plate of any one of Embodiments 57-61, wherein the laser scanning marks comprise microstructures having substantially different sizes or textures relative to sizes or textures of microstructures in regions of the laser-textured surface between adjacent laser scanning marks where laser scanning lines do not overlap.
63. The diffuser plate of any one of Embodiments 57-62, wherein the laser-textured surface comprises a plurality of regions, and wherein each region has an emissivity value different from those of neighboring regions by at least 10%.
64. The gas diffuser plate of Embodiment 63, wherein the plurality of regions is arranged as concentrically defined rings.

Although the present invention has been described herein with reference to the specific embodiments, these embodiments do not serve to limit the invention and are set forth for illustrative purposes. It will be apparent to those skilled in the art that modifications and improvements can be made without departing from the spirit and scope of the invention.

Such simple modifications and improvements of the various embodiments disclosed herein are within the scope of the disclosed technology, and the specific scope of the disclosed technology will be additionally defined by the appended Embodiments.

In the foregoing, it will be appreciated that any feature of any one of the embodiments can be combined or substituted with any other feature of any other one of the embodiments.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number, respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while features are presented in a given arrangement, alternative embodiments may perform similar functionalities with different components and/or sensor topologies, and some features may be deleted, moved, added, subdivided, combined, and/or modified. Each of these features may be implemented in a variety of different ways. Any suitable combination of the elements and acts of the various embodiments described above can be combined to provide further embodiments. The various features and processes described above may be implemented independently of one another, or may be combined in various ways. All possible combinations and subcombinations of features of this disclosure are intended to fall within the scope of this disclosure.

What is claimed is:

1. A gas diffuser plate configured to diffuse gases delivered into a cyclic deposition chamber, the gas diffuser plate as fabricated comprising:
a gas diffuser plate having a laser-textured surface configured to face a substrate when present in the cyclic deposition chamber,
wherein the laser-textured surface comprises microstructures to provide an emissivity of the gas diffuser plate between about 0.4 and about 0.9.

2. The gas diffuser plate of claim 1, wherein the laser-textured surface comprises stripes of laser scanning marks extending in a direction parallel to a laser scanning direction characteristic of laser texturing.

3. The gas diffuser plate of claim 2, wherein the stripes correspond to regions where laser scanning lines overlap.

4. The gas diffuser plate of claim 2, wherein the laser scanning marks comprise microstructures having substantially different sizes or textures relative to sizes or textures of microstructures in regions of the laser-textured surface between adjacent laser scanning marks where laser scanning lines do not overlap.

5. The gas diffuser plate of claim 1, further comprising a corrosion-resistant material coating the laser-textured surface.

6. The gas diffuser plate of claim 5, wherein the corrosion-resistant material substantially does not change the emissivity of the gas diffuser plate such that the gas diffuser plate having the corrosion-resistant material coated thereon has an emissivity between about 0.4 and about 0.9.

7. The gas diffuser plate of claim 1, wherein the emissivity of the gas diffuser plate is between about 0.4 and about 0.65.

8. The gas diffuser plate of claim 1, wherein the laser-textured surface is configured to modulate the emissivity of the gas diffuser plate to match an emissivity of a deposited material on the substrate.

9. The gas diffuser plate of claim 1, wherein the microstructures have a general shape of a dome or a pillar.

10. The gas diffuser plate of claim 1, wherein the microstructures have an average peak-to-valley height of about 1 micrometer to 10 micrometers.

11. The gas diffuser plate of claim 1, wherein the microstructures have an average peak-to-valley height of about 2 micrometers to 5 micrometers.

12. The gas diffuser plate of claim 1, wherein the microstructures have an average width measured at bases thereof of about 1 micrometer to 10 micrometers.

13. The gas diffuser plate of claim 1, wherein each microstructure comprises a metal core integrally protruding from a bulk substrate portion of the gas diffuser plate, and further comprises a layer of oxide formed on the metal core.

14. The gas diffuser plate of claim 1, wherein each microstructure has formed on a surface thereof a plurality of nanostructures, wherein the nanostructures have a maximum dimension that is smaller than a maximum dimension of the microstructures by at least two orders of magnitude.

15. The gas diffuser plate of claim 14, wherein the nanostructures comprise an average size of less than 10 nm.

16. The gas diffuser plate of claim 1, wherein the corrosion-resistant material is configured to reduce particle contamination generated from corrosion of the gas diffuser plate by a fluorine-containing cleaning gas.

17. The gas diffuser plate of claim 1, wherein the corrosion-resistant material is resistant to the corrosion of a fluorine-containing cleaning gas when present in the cyclic deposition chamber.

18. The gas diffuser plate of claim 17, wherein the fluorine-containing cleaning gas comprises NF₃, F₂, Ar, ClF₃, or combinations thereof.

19. The gas diffuser plate of claim 1, wherein the corrosion-resistant material comprises aluminum oxide.

20. The gas diffuser plate of claim 1, wherein the corrosion-resistant material is transparent or translucent.

21. The gas diffuser plate of claim 1, wherein the corrosion-resistant material is deposited by a method comprising atomic layer deposition (ALD).

22. The gas diffuser plate of claim 1, wherein the laser-textured surface reduces an amount of radiation emission from the substrate being reflected by the gas diffuser plate.

23. The gas diffuser plate of claim 1, wherein the laser-textured surface comprises a plurality of regions, and wherein each region has an emissivity value different from those of neighboring regions by at least 10%.

24. The gas diffuser plate of claim 23, wherein the plurality of regions is arranged as concentrically defined rings.
